(19) United States
(12) Patent Application Publication
(10) Pub. No.: US 2019/0040516 A1
(43) Pub. Date: Feb. 7, 2019

(54) MASK BLANK, METHOD FOR MANUFACTURING PHASE SHIFT MASK, AND METHOD FOR MANUFACTURING SEMICONDUCTOR DEVICE

(71) Applicant: HOYA CORPORATION, Tokyo (JP)

(72) Inventors: Ryo OHKUBO, Tokyo (JP); Osamu NOZAWA, Tokyo (JP); Hiroaki SHISHIDO, Tokyo (JP)

(73) Assignee: HOYA CORPORATION, Tokyo (JP)

(21) Appl. No.: 16/076,384

(22) PCT Filed: Jan. 17, 2017
(86) PCT No.: PCT/JP2017/001343

§ 371 Date: Aug. 8, 2018

(30) Foreign Application Priority Data
Feb. 15, 2016 (JP) 2016-025622

(51) Int. Cl. C23C 14/04; C23C 14/06; G03F 1/26; G03F 1/80; H01L 21/3065

(52) U.S. Cl. CPC C23C 14/042; C23C 14/0605; H01L 21/3065; G03F 1/80; G03F 1/26

(57) ABSTRACT

A mask blank having a light-shielding film containing chromium, oxygen, and carbon, and a hard mask film containing one or more of silicon and tantalum. The light shielding film and the hard mask film are provided in this order on a transparent substrate; the light shielding film being (1) a single layer film having a composition gradient portion with increased oxygen content on a surface at a side of the hard mask film and a region close thereto and (2) configured such that a maximum peak of N1s narrow spectrum obtained from X-ray photoelectron spectroscopy is less than or equal to lower detection limit. A portion of the light shielding film excluding the composition gradient portion has a chromium content of 50 atom % or more, and has a maximum peak of Cr2p narrow spectrum, obtained by X-ray photoelectron spectroscopy, at binding energy of 574 eV or less.

### TECHNICAL FIELD

This invention relates to a mask blank, a method for manufacturing a phase shift mask using the mask blank, and a method for manufacturing a semiconductor device using the phase shift mask manufactured from the mask blank.

### BACKGROUND

As a mask blank for a phase shift mask, a mask blank having a light shielding film made of a chromium-based material on a transparent substrate has been known. A phase shift mask formed using such a mask blank includes a light shielding pattern formed by patterning a light shielding film by dry etching using a mixed gas of chlorine-based gas and oxygen gas.

As a mask blank using a chromium-based material, use of a multilayer film of CrOC and CrOCN in combination as a light-shielding film and an antireflective film is suggested (e.g., see Publication 1).

On the other hand, as a mask blank for patterning a light shielding film through dry etching using a mixed gas of chlorine-based gas and oxygen gas, a suggestion is made on a structure having an etching mask film of silicon-based material such as SiO₂, SiN, and SiON on a light shielding film of a chromium-based material (e.g., see Publication 2). As materials suitable for an etching mask film, Publication 2 describes tantalum-based materials such as Ta, TaN, and TaON, in addition to the silicon-based material given above.

### PRIOR ART PUBLICATIONS

### Patent Publications

Publication 1:

Japanese Patent Application Publication 2001-305713

Publication 2:

Japanese Patent Application Publication 2014-137388

### SUMMARY OF THE INVENTION

### Problem to be Solved by the Invention

In dry etching of a light shielding film made of a chromium-based material, a mixed gas of chlorine-based gas and oxygen gas (oxygen-containing chlorine-based gas) is used as an etching gas. Generally, dry etching using the oxygen-containing chlorine-based gas as an etching gas has low tendency in anisotropic etching, and high tendency in isotropic etching.

Generally, in forming a pattern on a thin film through dry etching, etching advances not only in thickness direction of the film but also in side wall direction of the pattern formed on the thin film, which is so-called side etching. To suppress advancement of the side etching, it has been done in dry etching to apply bias voltage from the opposite side of the main surface on which a thin film of a substrate is formed, and to control so that more etching gas contacts in thickness direction of the film. In the case of ion-based dry etching using an etching gas that is likely to form an ionic plasma as fluorine-based gas, since applying bias voltage improves better controllability in etching direction and can enhance anisotropic property of etching, amount of side etching in the thin film to be etched can be minimized.

On the other hand, in the case of dry etching by oxygen-containing chlorine-based gas, since oxygen gas tends to form radical plasma, control of etching direction by applying bias voltage is less effective so that enhancing the anisotropic property of etching is difficult. Therefore, the amount of side etching tends to increase in the case of forming a pattern on a light shielding film made of a chromium-based material through dry etching using oxygen-containing chlorine-based gas.

In the case of patterning a light shielding film of a chromium-based material through dry etching using oxygen-containing chlorine-based gas with a resist pattern made of an organic-based material as an etching mask, the resist pattern is etched and decreased from the upper portion. In this circumstance, side wall direction of the resist pattern is also etched and decreased. Therefore, the width of the pattern to be formed on a resist film is designed beforehand allowing for a decreased amount due to side etching. Moreover, the width of the pattern to be formed on the resist film is designed allowing for the side etching amount of the light shielding film of a chromium-based material.

In recent years, a mask blank having a light shielding film of chromium-based material provided with a hard mask film thereon made of materials having sufficient etching selectivity between a chromium-based material relative to dry etching of oxygen-containing chlorine-based gas is beginning to be used. In this mask blank, a pattern is formed on a hard mask film through dry etching using a resist pattern as a mask. Subsequently, a light shielding film is subjected to dry etching of oxygen-containing chlorine-based gas with the hard mask film having a pattern as a mask to form a pattern on the light shielding film. This hard mask film is generally made of a material that can be patterned through dry etching of fluorine-based gas. Dry etching of fluorine-based gas is ion-based etching, having more tendency of anisotropic etching. Therefore, the pattern side wall of the hard mask film to which a transfer pattern is formed has less amount of side etching. Further, in the case of dry etching of fluorine-based gas, side etching amount tends to decrease also in a resist pattern for forming a pattern on the hard mask film. Therefore, demand has been growing for less side etching amount in dry etching of oxygen-containing chlorine-based gas for a light shielding film of chromium-based material as well.

As a means for solving the problem in side etching of a light shielding film of a chromium-based material, study is being made to significantly enhance the mixing ratio of chlorine-based gas in oxygen-containing chlorine-based gas in dry etching of oxygen-containing chlorine-based gas. This is because chlorine-based gas has high tendency to turn into ionic plasma. In dry etching using oxygen-containing chlorine-based gas with a higher ratio of chlorine-based gas, a decrease in the etching rate of a light shielding film of a chromium-based material is inevitable. To compensate for this decrease of etching rate of the light shielding film of a chromium-based material, study has been made to significantly increase bias voltage applied upon dry etching (dry etching using oxygen-containing chlorine-based gas with increased ratio of chlorine-based gas and carried out under application of high bias voltage is hereinafter referred to as “high-bias etching of oxygen-containing chlorine-based gas”).

The mask blank as described in Publication 1 given above has a structure where films of chromium-based materials having different compositions are stacked, having different etching rates depending on the composition of each film, and having different side etching amount for each film. In the case where this mask blank was used to pattern a light shielding film through dry etching by high bias etching, a large unevenness was formed on a cross-sectional shape of a pattern side wall formed in the light shielding film. Using such a mask blank with unevenness formed on a cross-sectional shape of the side wall to form a phase shift mask causes a reduction in pattern precision of the light shielding film.

For solving the above-mentioned problem, this invention provides a mask blank having a structure where a light shielding film made of a material containing chromium and a hard mask film formed in contact with the light shielding film are stacked in this order on a transparent substrate, in which when the light shielding film is patterned with the hard mask film as a mask using oxygen-containing chlorine-based gas as an etching gas, and under high-bias etching conditions, the pattern precision of the light shielding film having a pattern formed thereon can be maintained satisfactorily while significantly reducing the side etching amount. Moreover, this invention provides a method of manufacturing a phase shift mask in which by using the mask blank, a precise, fine pattern can be formed on the light shielding film. In addition, this invention provides a method of manufacturing a semiconductor device using the phase shift mask.

### Means for Solving the Problem

This invention includes the following structures as a means for solving the above-mentioned problem.

### (Structure 1)

A mask blank having a structure where a light shielding film and a hard mask film are stacked in this order on a transparent substrate,

in which the hard mask film is made of a material containing one or more elements selected from silicon and tantalum,

in which the light shielding film has an optical density to ArF excimer laser exposure light of more than 2.0,

in which the light shielding film is a single layer film having a composition gradient portion with increased oxygen content on a surface at aside of the hard mask film and a region close thereto,

in which the light shielding film is made of a material containing chromium, oxygen, and carbon,

in which a part of the light shielding film excluding the composition gradient portion has chromium content of 50 atom % or more,

in which the light shielding film has a maximum peak of N1s narrow spectrum, obtained by analysis of X-ray photoelectron spectroscopy, of lower detection limit or less, and

in which the part of the light shielding film excluding the composition gradient portion has a maximum peak of Cr2p narrow spectrum, obtained by analysis of X-ray photoelectron spectroscopy, at binding energy of 574 eV or less.

### (Structure 2)

The mask blank according to Structure 1, in which ratio of carbon content [atom %] divided by total content [atom %] of chromium, carbon, and oxygen of the part of the light shielding film excluding the composition gradient portion is 0.1 or more.

### (Structure 3)

The mask blank according to Structure 1 or 2, in which the composition gradient portion of the light shielding film has a maximum peak of Cr2p narrow spectrum obtained by analysis of X-ray photoelectron spectroscopy at binding energy of 576 eV or more.

### (Structure 4)

The mask blank according to any one of Structures 1 to 3, in which the light shielding film has a maximum peak of Si2p narrow spectrum obtained by analysis of X-ray photoelectron spectroscopy of lower detection limit or less.

### (Structure 5)

The mask blank according to any one of Structures 1 to 4, in which the part of the light shielding film excluding the composition gradient portion has chromium content of 80 atom % or less.

### (Structure 6)

The mask blank according to any one of Structures 1 to 5, in which the part of the light shielding film excluding the composition gradient portion has carbon content of 10 atom % or more and 20 atom % or less.

### (Structure 7)

The mask blank according to any one of Structures 1 to 6, in which the part of the light shielding film excluding the composition gradient portion has oxygen content of 10 atom % or more and 35 atom % or less.

### (Structure 8)

The mask blank according to any one of Structures 1 to 7, wherein, in the part of the light shielding film excluding the composition gradient portion, difference in content of each constituent element in thickness direction is less than 10 atom % for all the constituent elements.

### (Structure 9)

The mask blank according to any one of Structures 1 to 8, in which the light shielding film has a thickness of 80 nm or less.

### (Structure 10)

A method of manufacturing a phase shift mask using the mask blank according to any one of Structures 1 to 9, including the steps of:

forming a light shielding pattern on the hard mask film through dry etching using fluorine-based gas with a resist film having a light shielding pattern formed on the hard mask film as a mask;

forming a light shielding pattern on the light shielding film through dry etching using a mixed gas of chlorine-based gas and oxygen gas with the hard mask film having the light shielding pattern formed thereon as a mask; and

forming a dug-down pattern on the transparent substrate through dry etching using fluorine-based gas with a resist film having a dug-down pattern formed on the light shielding film as a mask.

### (Structure 11)

A method of manufacturing a semiconductor device including the step of exposure-transferring a transfer pattern on a resist film on a semiconductor substrate using a phase shift mask obtained by the method of manufacturing a phase shift mask of Structure 10.

### Effect Of Invention

According to the mask blank of this invention including the above structures, in a mask blank having a structure where a light shielding film made of a material containing chromium and a hard mask film are stacked in this order on a transparent substrate, even if the light shielding film was patterned through dry etching using oxygen-containing chlorine-based gas as an etching gas and under high-bias etching condition, the side etching amount of the pattern of the light shielding film formed thereby can be significantly reduced, and a precise, fine pattern can be formed on the light shielding film. Therefore, a phase shift mask having a highly precise and fine transfer pattern can be obtained. Moreover, in manufacturing a semiconductor device using the phase shift mask, a pattern can be transferred on a resist film, etc. on the semiconductor device with high precision.

### BRIEF DESCRIPTION OF THE DRAWINGS

FIG. 1 is a schematic cross-sectional view of an embodiment of the mask blank.

FIG. 2 is a schematic cross-sectional view showing a manufacturing step of a phase shift mask.

FIG. 3 is a schematic cross-sectional view showing a manufacturing step of a phase shift mask.

FIG. 4 shows a result (Cr2p narrow spectrum) where the light shielding film of the mask blank of Example 1 was subjected to XPS analysis (depth direction chemical bonding condition analysis).

FIG. 5 shows a result (O1s narrow spectrum) where the light shielding film of the mask blank of Example 1 was subjected to XPS analysis (depth direction chemical bonding condition analysis).

FIG. 6 shows a result (N1s narrow spectrum) where the light shielding film of the mask blank of Example 1 was subjected to XPS analysis (depth direction chemical bonding condition analysis).

FIG. 7 shows a result (C1s narrow spectrum) where the light shielding film of the mask blank of Example 1 was subjected to XPS analysis (depth direction chemical bonding condition analysis).

FIG. 8 shows a result (Si2p narrow spectrum) where the light shielding film of the mask blank of Example 1 was subjected to XPS analysis (depth direction chemical bonding condition analysis).

FIG. 9 shows a result (Cr2p narrow spectrum) where the light shielding film of the mask blank of Example 2 was subjected to XPS analysis (depth direction chemical bonding condition analysis).

FIG. 10 shows a result (O1s narrow spectrum) where the light shielding film of the mask blank of Example 2 was subjected to XPS analysis (depth direction chemical bonding condition analysis).

FIG. 11 shows a result (N1s narrow spectrum) where the light shielding film of the mask blank of Example 2 was subjected to XPS analysis (depth direction chemical bonding condition analysis).

FIG. 12 shows a result (C1s narrow spectrum) where the light shielding film of the mask blank of Example 2 was subjected to XPS analysis (depth direction chemical bonding condition analysis).

FIG. 13 shows a result (Si2p narrow spectrum) where the light shielding film of the mask blank of Example 2 was subjected to XPS analysis (depth direction chemical bonding condition analysis).

FIG. 14 shows a result (Cr2p narrow spectrum) where the light shielding film of the mask blank of Comparative Example 1 was subjected to XPS analysis (depth direction chemical bonding condition analysis).

FIG. 15 shows a result (O1s narrow spectrum) where the light shielding film of the mask blank of Comparative Example 1 was subjected to XPS analysis (depth direction chemical bonding condition analysis).

FIG. 16 shows a result (N1s narrow spectrum) where the light shielding film of the mask blank of Comparative Example 1 was subjected to XPS analysis (depth direction chemical bonding condition analysis).

FIG. 17 shows a result (C1s narrow spectrum) where the light shielding film of the mask blank of Comparative Example 1 was subjected to XPS analysis (depth direction chemical bonding condition analysis).

FIG. 18 shows a result (Si2p narrow spectrum) where the light shielding film of the mask blank of Comparative Example 1 was subjected to XPS analysis (depth direction chemical bonding condition analysis).

### EMBODIMENTS FOR CARRYING OUT THE INVENTION

The embodiments of this invention are explained below. First, the background of this invention is explained. As chromium (Cr)-based materials constructing conventional mask blanks, materials containing nitrogen (N) such as CrON and CrOCN are known. This is because defect quality of a chromium-based material film is enhanced by using nitrogen gas in addition to oxygen-containing gas as a reactive gas when forming a chromium-based material film by the sputtering method. Further, by combining nitrogen in a chromium-based material film, the etching rate of dry etching by oxygen-containing chlorine-based gas increases. On the other hand, a film-forming method where presputtering is carried out upon forming a film of a Cr-based material is being done in a chromium-based material film. Since this presputtering can reduce quality defect of a chromium-based material film, film-forming without the use of N₂ gas for reducing quality defect is possible.

As mentioned above, in dry etching a chromium-based material film by high-bias etching, the etching rate in film thickness direction can be increased significantly compared to dry etching using the same etching gas condition under normal bias voltage (hereinafter referred to as “dry etching in normal conditions”). Normally, in dry etching of a thin film, both of chemical reaction etching and physical action etching are carried out. Chemical reaction etching is carried out through a process where etching gas in a plasma state contacts a surface of the thin film and bonds to metal elements in the thin film to produce a compound of a low boiling point for sublimation. In chemical reaction etching, bonding of metal elements in bonding condition with other elements is broken to produce a compound with a low boiling point. On the contrary, physical action etching is carried out through a process where ionic plasma in etching gas accelerated by bias voltage collides upon the surface of a thin film (a phenomena referred to as “ion bombardment”), so as to physically eject away each element including metal elements on the surface of the thin film (at which the bond between elements is broken), and a compound of low boiling point is produced with the metal elements for sublimation.

High-bias etching is an etching where dry etching by physical action is enhanced compared to dry etching in a normal conditions. Physical action etching contributes significantly to etching in film thickness direction, but contributes less to etching in side wall direction of a pattern. On the contrary, chemical reaction etching contributes to both etching in film thickness direction and etching in side wall direction of a pattern. Therefore, to reduce the side etching amount further, it is necessary to reduce easiness of being etched by chemical reaction in a light shielding film of a chromium-based material more, as well as maintaining easiness in dry etching by physical action at the same level as before.

The simplest approach to reduce the etching amount by chemical reaction etching of a light shielding film of a chromium-based material is to increase the chromium content in the light shielding film. However, forming the light shielding film only from chromium metal causes a significant reduction in the etching amount of dry etching by physical action. Even in the case of dry etching by physical action, unless the chromium element ejected out from the film bonds with chlorine and oxygen to form chromyl chloride (CrO₂Cl₂: compound of chromium with low boiling point), chromium elements re-attach to the light shielding film and cannot be removed. Since there is a limit to increase the supply of etching gas, an excess amount of chromium content in the light shielding film causes a significant reduction in the etching rate of the light shielding film.

A significant reduction of the etching rate of a light shielding film causes significant increase in etching time when patterning the light shielding film. An increase in the etching time when patterning the light shielding film causes an increase in time of which a side wall of the light shielding film is exposed to etching gas, resulting in an increase of the side etching amount. An approach to significantly reduce the etching rate of a light shielding film such as increasing the chromium content in the light shielding film does not lead to suppression of the side etching amount.

Therefore, an earnest investigation was made on constituent elements in a light shielding film other than chromium. To suppress the side etching amount, it is effective to include light elements that consume oxygen radical that promotes chemical reaction etching. Since the material for forming a light shielding film needs to have at least patterning characteristics, light-shielding performance, chemical resistance upon cleaning, etc. of more than a certain level, light elements that can be included in a chromium-based material forming the light shielding film for more than a certain amount are limited. Typical light elements that can be included in a chromium-based material for more than a certain amount include oxygen, nitrogen, and carbon. Combining oxygen in a chromium-based material forming a light shielding film can significantly increase the etching rate in both high-bias etching and dry etching in normal conditions. Although side etching is likely to advance at the same time, etching time in film thickness direction is significantly shortened so that time of which a side wall of the light shielding film is exposed to the etching gas is shortened. Considering these circumstances, it is necessary to include oxygen in a chromium-based material forming a light shielding film in the case of high-bias etching.

When nitrogen is added to a chromium-based material forming a light shielding film, although not as significant as the case of including oxygen, the etching rate increases in both high-bias etching and dry etching of normal condition. However, side etching is also likely to advance. Considering that side etching is more likely to advance compared to the degree of etching time in film thickness direction being shortened by including nitrogen in a chromium-based material forming a light shielding film, in the case of high-bias etching, it is considered preferable not to include nitrogen in a chromium-based material forming a light shielding film.

In the case of dry etching of normal condition, when carbon is included in a chromium-based material forming a light shielding film, the etching rate is slightly reduced compared to the case of a light shielding film formed only from chromium. However, when carbon is included in a chromium-based material forming a light shielding film, durability to physical action etching is reduced compared to the case of a light shielding film formed only from chromium. Therefore, when carbon is included in a chromium-based material forming a light shielding film in the case of high-bias etching, the etching rate is increased compared to the case of a light shielding film formed only from chromium. Further, when carbon is included in a chromium-based material forming a light shielding film, since oxygen radical that promotes side etching is consumed, side etching is less likely to advance compared to the case of including oxygen or nitrogen. Considering the above, in the case of high-bias etching, it is necessary that a chromium-based material forming a light shielding film contains carbon.

Occurrence of such significant difference between the case of including nitrogen and the case of including carbon in a material forming a light shielding film is due to a difference between Cr—N bond and Cr—C bond. Cr—N bond has low binding energy (bound energy) and bonding tends to disassociate easily. Therefore, contact of oxygen and chlorine in the form of plasma causes Cr-N bond to disassociate and tends to easily form chromyl chloride of low boiling point. On the contrary, Cr—C bond has high binding energy and is less likely to disassociate. Therefore, despite the contact of oxygen and chlorine in the form of plasma, it is less likely that Cr—C bond is disassociated to form chromyl chloride of low boiling point.

High-bias etching has a great tendency of dry etching by physical action. While elements in a thin film are ejected out by ion bombardment in dry etching by physical action, the bond between each element tends to break in such circumstances. Therefore, the difference in easiness of production of chromyl chloride that occurs due to the difference in degree of binding energy between elements is smaller compared to the case of chemical reaction etching. Etching by physical action that occurs by bias voltage significantly contributes to etching in film thickness direction, but not as much in etching in side wall direction of a pattern. Therefore, in high-bias etching of a light shielding film in film thickness direction, there is less difference in easiness of etching between Cr—N bond and Cr—C bond.

On the contrary, side etching that advances in side wall direction of a light shielding film has a high tendency of chemical reaction etching. Therefore, if the abundance ratio of Cr—N bond is high in a material forming a light shielding film, side etching is likely to advance. On the other hand, if the abundance ratio of Cr—C bond is high in a material forming alight shielding film, side etching is less likely to advance.

As a result of comprehensive consideration of the above, the following result was obtained. Namely, a light shielding film that is to be dry etched through high-bias etching using a hard mask film having a pattern formed thereon as an etching mask is a single layer film having a composition gradient portion with increased oxygen content at and near a surface at the hard mask film side, in which the light shielding film is made of a material containing chromium, oxygen, and carbon; a portion of the light shielding film excluding the composition gradient portion has chromium content of 50 atom % or more; a maximum peak of N1s narrow spectrum obtained by analysis of X-ray photoelectron spectroscopy (XPS) of the light shielding film is lower detection limit or less; and Cr2p narrow spectrum obtained by analysis of X-ray photoelectron spectroscopy of the portion of the light shielding film excluding the composition gradient portion has a maximum peak at binding energy of 574 eV or less.

Detailed structures of this invention given above are explained based on the drawings. Reference numerals applied in the drawings are used for similar components.

### Mask Blank

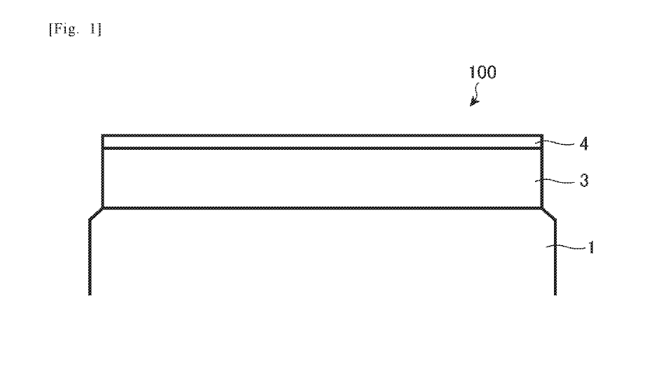

FIG. 1 shows a schematic structure of an embodiment of a mask blank. A mask blank 100 shown in FIG. 1 has a structure where one main surface of a transparent substrate 1 has a light shielding film 3, and a hard mask film 4 stacked in this order. Further, the mask blank 100 can have a structure where the hard mask film 4 has a resist film stacked thereon as desired. The detail of major structure of the mask blank 100 is explained below.

### Transparent Substrate

The transparent substrate 1 is made of materials having good transmittance to exposure light used in an exposure step. Such materials include synthetic quartz glass, aluminosilicate glass, soda-lime glass, low thermal expansion glass (SiO₂ -TiO₂ glass, etc.), and various other glass substrates can be used. Particularly, a substrate using synthetic quartz glass has high transmittance to ArF excimer laser light (wavelength: about 193 nm), which can be used preferably as the transparent substrate 1 of the mask blank 100.

The exposure step as used herein indicates a step where a transfer mask (phase shift mask) manufactured by using the mask blank 100 is set on a mask stage of an exposure apparatus, irradiating exposure light, and exposure-transferring a transfer pattern (phase shift pattern) on an object to be transferred. The exposure light means exposure light used in the exposure step. As the exposure light, any one of ArF excimer laser light (wavelength: 193 nm), KrF excimer laser light (wavelength: 248 nm), and i-line light (wavelength: 365 nm) can be applied, but in view of miniaturizing a transfer pattern in the exposure step, it is preferable to apply ArF excimer laser light as the exposure light. Therefore, embodiments in the case where ArF excimer laser light is applied as exposure light are described below.

### Light Shielding Film

The light shielding film 3 is a film on which a light shielding pattern is formed in manufacturing a transfer mask from the mask blank 100, having light shielding property to exposure light. The light shielding film 3 is desired to have more than 2.0, preferably 2.8 or more, and more preferably 3.0 or more optical density (OD) to, for example, ArF excimer laser light of wavelength 193 nm. Further, in an exposure step, to prevent defects in exposure transfer by reflection of exposure light, surface reflectance of the light shielding film 3 to exposure light is suppressed at a low rate at each of the front side (surface of the farthest side from the transparent substrate 1) and the back side (surface at the transparent substrate 1 side). Particularly, reflectance of the surface of the front side of the light shielding film 3 onto which reflected light of exposure light from an optical reduction system of an exposure apparatus hits is preferably, for example, 40% or less (preferably 30% or less). This is to suppress stray light generated from multiple reflections between the surface of the front side of the light shielding film 3 and the optical reduction system lens.

Further, the light shielding film 3 should function as an etching mask upon dry etching by fluorine-based gas for forming a dug-down pattern on the transparent substrate 1.

Therefore, the light shielding film 3 should be made from materials having sufficient etching selectivity to the transparent substrate 1 upon dry etching by fluorine-based gas. It is necessary for the light shielding film 3 to precisely form a fine light shielding pattern. Film thickness of the light shielding film 3 is preferably 80 nm or less, and more preferably 75 nm or less. When the film thickness of the light shielding film 3 is too thick, the fine pattern to be formed cannot be created at a high precision. On the other hand, it is necessary for the light shielding film 3 to satisfy the required optical density as given above. Therefore, the film thickness of the light shielding film 3 is desired to be greater than 30 nm, preferably 35 nm or more, and further preferably 40 nm or more.

The light shielding film 3 is made of a material containing chromium (Cr), oxygen (O), and carbon (C). Further, the light shielding film 3 includes a single layer film having a composition gradient portion with increasing oxygen content on the surface at the hard mask film 4 side and region close thereto. This is caused by, in the manufacturing step, since the surface of the formed light shielding film 3 is exposed to an oxygen-containing atmosphere, a region containing an increased amount of oxygen content than other regions is formed only on the surface of the light shielding film 3. This oxygen content is highest at the surface that is exposed to the oxygen-containing atmosphere, and the oxygen content moderately decreases with the distance from the surface. Composition of the light shielding film 3 becomes substantially constant from a position away for a certain distance from the surface. The region where oxygen content varies (moderately decreases) from the surface of the light shielding film 3 is regarded as a composition gradient portion. Further, in the light shielding film 3 at regions other than the composition gradient portion, the difference in content amount of each element in film thickness direction is preferably less than 10 atom %, more preferably 8 atom % or less, and further preferably 5 atom % or less. Incidentally, the composition gradient portion of the light shielding film 3 is preferably a region up to the depth of less than 5 nm from the surface, more preferably a region up to the depth of 4 nm or less, and further preferably a region up to the depth of 3 nm or less.

The portion of the light shielding film 3 excluding the composition gradient portion has chromium content of 50 atom % or more. This is for suppressing side etching that generates when patterning the light shielding film 3 through high-bias etching. On the other hand, the portion of the light shielding film 3 excluding the composition gradient portion preferably includes chromium content of 80 atom % or less. This is for securing a sufficient etching rate when patterning the light shielding film 3 through high-bias etching.

A maximum peak of N1s narrow spectrum obtained by analysis of X-ray photoelectron spectroscopy of the light shielding film 3 is lower detection limit or less. If there exists a peak of N1s narrow spectrum, there should be a predetermined ratio or more of Cr—N bond in the material forming the light shielding film 3. If there exists a predetermined ratio or more of Cr—N bond in a material forming the light shielding film 3, it would be difficult to suppress advancement of side etching when patterning the light shielding film 3 through high-bias etching. Content of nitrogen (N) in the light shielding film 3 is preferably the detection limit amount or less in composition analysis of X-ray photoelectron spectroscopy.

Cr2p narrow spectrum obtained by analysis of X-ray photoelectron spectroscopy of the portion of the light shielding film 3 excluding the composition gradient portion has a maximum peak at binding energy of 574 eV or less. The case of the state where Cr2p narrow spectrum of a material containing Cr has a maximum peak at binding energy higher than 574 eV, namely, the state of a chemical shift, shows a state where abundance ratio of chromium atoms bonded to other atoms (particularly nitrogen) is high. Such a chromium-based material tends to have low durability to chemical reaction-based etching, and it is difficult to suppress side etching. By forming the portion of the light shielding film 3 excluding the composition gradient portion from a chromium-based material where Cr2p narrow spectrum has a maximum peak at binding energy of 574 eV or less, advancement of side etching when patterned through high-bias etching can be suppressed. Incidentally, Cr2p narrow spectrum at the portion of the light shielding film 3 excluding the composition gradient portion preferably has a maximum peak at binding energy of 570 eV or less.

The ratio of carbon content [atom %] of the portion of the light shielding film 3 excluding the composition gradient portion divided by total content [atom %] of chromium, carbon, and oxygen is preferably 0.1 or more, and more preferably 0.14 or more. As mentioned above, a major part of the light shielding film 3 is occupied by chromium, oxygen, and carbon. The majority of chromium in the light shielding film 3 exists in any of the form of Cr—O bond, the form of Cr—C bond, and in the form not bonded to oxygen and carbon. The Cr-based material having high ratio of carbon content [atom %] divided by total content [atom %] of chromium, carbon, and oxygen has high abundance ratio of Cr-C bond in the material, and applying such a Cr-based material to the light shielding film 3 can suppress advancement of side etching when patterned through high-bias etching. Incidentally, ratio of content [atom %] of carbon in the portion of the light shielding film 3 excluding the composition gradient portion divided by total content [atom %] of chromium and carbon is preferably 0.14 or more, and more preferably, 0.16 or more.

The total content of chromium, oxygen, and carbon of the light shielding film 3 is preferably 95 atom % or more, and more preferably, 98 atom % or more. The light shielding film 3 is particularly preferably made of chromium, oxygen, and carbon, except for impurities that are inevitably mixed. Incidentally, the impurities that are inevitably mixed herein indicate elements that are inevitably mixed when forming the light shielding film 3 through sputtering method such as argon (Ar), helium (He), neon (Ne), krypton (Kr), xenon (Xe), and hydrogen (H). The portion of the light shielding film 3 excluding the composition gradient portion preferably has oxygen content of 10 atom % or more and 35 atom % or less. Further, the portion of the light shielding film 3 excluding the composition gradient portion preferably has carbon content of 10 atom % or more and 20 atom % or less.

It is preferable that Cr2p narrow spectrum obtained by analysis of X-ray photoelectron spectroscopy of the composition gradient portion of the light shielding film 3 has a maximum peak at binding energy of 576 eV or more. It is preferable that Cr2p narrow spectrum of the composition gradient portion of the light shielding film 3 has a maximum peak at binding energy of 580 eV or less. Moreover, it is preferable that Si2p narrow spectrum obtained by analysis of X-ray photoelectron spectroscopy of the light shielding film 3 has a maximum peak of lower detection limit or less. Existence of peak of Si2p narrow spectrum will show existence of predetermined ratio or more of unbonded silicon or silicon bonded to other atoms in the material forming the light shielding film 3. Such a material is not preferable, since the etching rate to dry etching by oxygen-containing chlorine-based gas tends to decrease. It is preferable for the light shielding film 3 to have silicon content of 1 atom % or less, and preferably detection limit or less by composition analysis using an X-ray photoelectron spectroscopy.

The method of obtaining Cr2p narrow spectrum, O1s narrow spectrum, C1s narrow spectrum, N1s narrow spectrum, and Si2p narrow spectrum through X-ray photoelectron spectroscopy on the light shielding film 3 is generally carried out by the following procedures. Namely, initially, wide-scanning is carried out to acquire photoelectron intensity (number of discharge of photoelectrons per unit time from X ray-irradiated measurement object) at a band width of a wide range of binding energy to acquire wide spectrum, and all peaks derived from the constituent elements of the light shielding film 3 are specified. Subsequently, each narrow spectrum is acquired by performing narrow scanning, which has a higher resolution than wide scan but bandwidth of binding energy that can be obtained is narrow, with band width around the peaks of interest (Cr2p, O1s, C1s, N1s, Si2p, etc.). On the other hand, in the case where the constituent elements of the light shielding film 3 are known previously, the step of obtaining wide spectrum can be omitted and Cr2p narrow spectrum, O1s narrow spectrum, C1s narrow spectrum, N1s narrow spectrum, and Si2p narrow spectrum can be obtained.

Cr2p narrow spectrum of the light shielding film 3 is obtained within the range of, e.g., 566 eV-600 eV binding energy. It is more preferable that Cr2p narrow spectrum of the light shielding film 3 includes the range of 570 eV-580 eV binding energy. O1s narrow spectrum of the light shielding film 3 is obtained within the range of, e.g., 524 eV-540 eV binding energy. It is more preferable that O1s narrow spectrum of the light shielding film 3 includes the range of 528 eV-534 eV binding energy. N1s narrow spectrum of the light shielding film 3 is obtained within the range of, e.g., 390 eV-404 eV binding energy. It is more preferable that N1s narrow spectrum of the light shielding film 3 includes the range of 395 eV-400 eV binding energy. C1s narrow spectrum of the light shielding film 3 is obtained within the range of, e.g., 278 eV-296 eV binding energy. It is more preferable that C1s narrow spectrum of the light shielding film 3 includes the range of 280 eV-285 eV binding energy. Si2p narrow spectrum of the light shielding film 3 is obtained within the range of, e.g., 95 eV˜110 eV binding energy.

The light shielding film 3 can be formed on the transparent substrate 1 through the reactive sputtering method using a target containing chromium. As the sputtering method, a sputtering using direct current (DC) power source (DC sputtering), or a sputtering using radio-frequency (RF) power source (RF sputtering) can be used. In addition, the magnetron sputtering method and conventional method can also be used. DC sputtering is preferable for having a simple mechanism. The magnetron sputtering method is preferable for increasing deposition rate and enhancing productivity. Incidentally, a film-forming apparatus can be an in-line type or a single-wafer type.

As a sputtering gas to be used in forming the light shielding film 3, preferable gas is one of a mixed gas of gas free of oxygen and containing carbon (CH₄, C₂H₄, C₂H₆, etc.), gas free of carbon and containing oxygen (O₂, O₃, etc.), and noble gas (Ar, Kr, Xe, He, Ne, etc.), and a mixed gas of gas containing carbon and oxygen (CO₂, CO, etc.) and noble gas, or gas containing noble gas, carbon, and oxygen and containing at least one of gas free of oxygen and containing carbon (CH₄, C₂H₄, C₂H₆, etc.) and gas free of carbon and containing oxygen. Particularly, it is safe to use a mixed gas of CO₂ and noble gas as sputtering gas, and CO₂ gas can be distributed uniformly through a wide range in a chamber for being less reactive than oxygen gas, thus preferable in view of forming a uniform film quality of the light shielding film 3 to be formed. As for the introduction method, the gas can be introduced separately into the chamber, or can be introduced by mixing some or all gases.

Materials of the target can include, not only a simple substance of chromium, but chromium as a major substance, and chromium including any one of oxygen and carbon, or a combination of oxygen and carbon added to chromium can be used as the target.

### Hard Mask Film

The hard mask film 4 is provided in contact with a surface of the light shielding film 3. The hard mask film 4 is a film made of a material having etching durability to etching gas used in etching the light shielding film 3. It is sufficient for the hard mask film 4 to have film thickness that can function as an etching mask until dry etching for forming a pattern on the light shielding film 3 is completed, and is not basically subjected to limitation of optical characteristics. Therefore, the thickness of the hard mask film 4 can be significantly less than the thickness of the light shielding film 3.

The thickness of the hard mask film 4 is required to be 20 nm or less, preferably 15 nm or less, and more preferably 10 nm or less. This is because if the hard mask film 4 is too thick, a resist film, which is an etching mask in dry etching for forming a light shielding pattern on the hard mask film 4, needs to have thickness. Thickness of the hard mask film 4 is required to be 3 nm or more, and preferably 5 nm or more. This is because if the hard mask film 4 is too thin, there is a risk that the pattern of the hard mask film 4 disappears before completion of dry etching in forming a light shielding pattern on the light shielding film 3 depending on the condition of high-bias etching by oxygen-containing chlorine-based gas.

It is sufficient for the resist film of an organic-based material used as an etching mask in dry etching by fluorine-based gas for forming a pattern on the hard mask film 4 to have a film thickness that can function as an etching mask until dry etching of the hard mask film 4 is completed. Therefore, providing the hard mask film 4 can significantly reduce the thickness of the resist film compared to conventional structures without the hard mask film 4.

The hard mask film 4 is preferably made of a material containing one or more elements selected from silicon and tantalum. In the case of forming the hard mask film 4 from a material containing silicon, it is preferable to apply SiO₂, SiN, SiON, etc. Since the hard mask film 4 in this case tends to have low adhesiveness with a resist film of an organic-based material, it is preferable to subject the surface of the hard mask film 4 to HMDS (Hexamethyldisilazane) treatment to enhance surface adhesiveness.

Further, in the case of forming the hard mask film 4 from a material containing tantalum, it is preferable to apply, other than tantalum metal, a material including tantalum containing one or more elements selected from nitrogen, oxygen, boron, and carbon, for example, Ta, TaN, TaO, TaON, TaBN, TaBO, TaBON, TaCN, TaCO, TaCON, TaBCN, and TaBOCN. The hard mask film 4 contains tantalum (Ta) and oxygen (O), which is preferably made of O content of 50 atom % or more (hereinafter referred to as TaO-based material).

It is necessary for the hard mask film 4 to have sufficiently high etching durability to high-bias etching in patterning the light shielding film 3. Insufficient etching durability causes etching on an edge portion of the pattern of the hard mask film 4 causing reduction of the mask pattern, which degrades precision of a light shielding pattern. By including at least 50 atom % or more oxygen content in a material containing Ta, durability to dry etching by oxygen-containing chlorine-based gas can be significantly enhanced.

It is preferable that the hard mask film 4 of TaO-based material has a microcrystalline crystal structure, preferably amorphous. When crystal structure in the hard mask film 4 of TaO-based material is microcrystalline or amorphous, the structure is unlikely to become a single structure and is likely to become a condition where a plurality of crystal structures is mixed. Therefore, TaO-based material in the hard mask film 4 is likely to form a condition where TaO bond, Ta₂O₃ bond, TaO₂ bond, and Ta₂O₅ bond are mixed (mixed crystal state). As abundance ratio of Ta₂O₅ bond increases in TaO-based material in the hard mask film 4, durability to dry etching by oxygen-containing chlorine-based gas tends to be enhanced. Further, as abundance ratio of Ta₂O₅ bond increases in TaO-based material in the hard mask film 4, property to prevent hydrogen intrusion, chemical resistance, resistance to hot water, and ArF light fastness also tend to be enhanced.

When oxygen content in the hard mask film 4 of TaO-based material is 50 atom % or more and less than 66.7 atom %, it is considered that Ta₂O₃ bond tends to be the majority of the bonding condition of tantalum and oxygen in the film, and it is considered that the amount of TaO bond which is the most unstable bond becomes extremely small compared to the case where oxygen content in the film is less than 50 atom %. When the oxygen content in the film is 66.7 atom % or more in the hard mask film 4 of TaO-based material, it is considered that TaO₂ bond tends to be the majority of the bonding condition of tantalum and oxygen, and it is considered that the amounts of TaO bond which is the most unstable bond and Ta₂O₃ bond which is an unstable bond next thereto both become extremely small.

Further, if the hard mask film 4 of TaO-based material has oxygen content of 67 atom % or more in the film, it can be considered that not only TaO₂ bond becomes the majority, but the ratio of bonding condition of Ta₂O₅ also becomes higher. In such oxygen content, bonding condition of TaO₂, and Ta₂O₃ rarely exist, and renders bonding condition of TaO to hardly exist. If the hard mask film 4 of TaO-based material has oxygen content in the film of about 71.4 atom %, the film is considered as formed substantially only from bonding condition of Ta₂O₅ (since the oxygen content of Ta₂O₅, the most oxidized bonding condition, is 71.4 atom %).

If the hard mask film 4 of TaO-based material has oxygen content of 50 atom % or more, the film will include not only Ta₂O₅ with most stable bonding condition, but also bonding condition of TaO₂ and Ta₂O₃. On the other hand, in the hard mask film 4 of TaO-based material, the lowest limit of oxygen content including less amount of TaO bond, which is the most unstable bond, within the range of not affecting dry etching durability, is considered as at least 50 atom %.

Ta₂O₅ bond is a bonding condition having an extremely high stability, and durability to high-bias etching can be enhanced significantly by increasing abundance ratio of Ta₂O₅ bond. Further, mask cleaning durability such as property to prevent hydrogen intrusion, chemical resistance, and resistance to hot water, and ArF light fastness are enhanced significantly.

Particularly, it is most preferable that TaO forming the hard mask film 4 is formed only from bonding condition of Ta₂O₅. Incidentally, nitrogen and other elements in the hard mask film 4 of TaO-based material are preferably within the range of not affecting these functional effects, and more preferably substantially free thereof.

Further, by forming the hard mask film 4 of TaO-based material from a material where a maximum peak of Ta4f narrow spectrum obtained by analysis of X-ray photoelectron spectroscopy is higher than 23 eV, durability to high-bias etching can be significantly enhanced. Material having high binding energy tends to enhance durability to dry etching by oxygen-containing chlorine-based gas. Further, property to prevent hydrogen intrusion, chemical resistance, resistance to hot water, and ArF light fastness also tend to be enhanced. Bonding condition having the highest binding energy in tantalum compounds is Ta₂O₅ bond.

In a material containing tantalum where a maximum peak of Ta4f narrow spectrum is 23 eV or less, Ta₂O₅ bond is less likely to exist. Therefore, the hard mask film 4 of TaO-based material preferably has a maximum peak of Ta4f narrow spectrum obtained by analysis of X-ray photoelectron spectroscopy of 24 eV or more, more preferably 25 eV or more, and particularly preferably 25.4 eV or more. When a maximum peak of Ta4f narrow spectrum obtained by analysis of X-ray photoelectron spectroscopy is 25 eV or more, the bonding condition of tantalum and oxygen in the hard mask film 4 will mainly be Ta₂O₅ bond, significantly enhancing durability to high-bias etching.

TaO-based material forming the hard mask film 4 having oxygen content of 50 atom % tends to have tensile stress. On the contrary, material containing chromium, oxygen, and carbon as main components (CrOC-based material) forming the light shielding film 3 tends to have compressive stress. Generally, annealing is carried out as a treatment to reduce stress of a thin film. However, since it is difficult to heat a thin film of a chromium-based material under high temperature of 300 degrees or more, it is difficult to reduce the compressive stress of CrOC-based material down to zero. As in the mask blank 100 of this embodiment, by forming a structure where the hard mask film 4 of TaO-based material is stacked on the light shielding film 3 of CrOC-based material, compensation occurs between compressive stress of the light shielding film 3 and tensile stress of the hard mask film 4 so that stress of the entire stacked structure can be reduced.

### Resist Film

In the mask blank 100, a resist film made of an organic-based material is preferably formed at a film thickness of 100 nm or less in contact with a surface of the hard mask film 4. In the case of a fine pattern compatible with the DRAM hp32 nm generation, SRAF (Sub-Resolution Assist Feature) having a line width of 40 nm may be provided in a light shielding pattern that is to be formed on the light shielding film 3. However, also in this case, as described above, the film thickness of the resist film can be suppressed as a result of providing the hard mask film 4, and as a consequence, a cross-sectional aspect ratio of the resist pattern formed of the resist film can be set as low as 1:2.5. Therefore, collapse or peeling off of the resist pattern during the development, rinsing, and the like of the resist film can be suppressed. It is more preferable that the resist film has a film thickness of 80 nm or less. The resist film is preferably a resist for electron beam writing exposure, and it is more preferable that the resist is a chemically amplified resist.

### Mask Blank Manufacturing Process

The mask blank 100 of the above structure is manufactured through the following procedure. First, a transparent substrate 1 is prepared. This transparent substrate 1 includes an end surface and a main surface polished into a predetermined surface roughness (e.g., root mean square roughness Rq of 0. 2 nm or less in an inner region of a square of 1 μm side), and thereafter subjected to predetermined cleaning treatment and drying treatment.

Next, a light shielding film 3 is formed on the transparent substrate 1 by sputtering method. Subsequently, the hard mask film 4 is formed on the light shielding film 3 by sputtering method. In formation of each layer by sputtering method, the sputtering target and sputtering gas containing materials forming each layer at a predetermined composition ratio are used, and moreover, the mixed gas of noble gas and reactive gas mentioned above is used as sputtering gas as necessary. Thereafter, in the case where the mask blank 100 includes a resist film, the surface of the hard mask film 4 is subjected to HMDS (Hexamethyldisilazane) treatment as necessary. Next, a resist film is formed by coating methods such as spin coating on the surface of the hard mask film 4 subjected to HMDS treatment to complete the mask blank 100.

### Method of Manufacturing Phase Shift Mask

Next, the manufacturing method of a phase shift mask according to this embodiment will be explained, with the manufacturing method of a dug-down Levenson type phase shift mask using the mask blank 100 of the structure shown in FIG. 1 as an example.

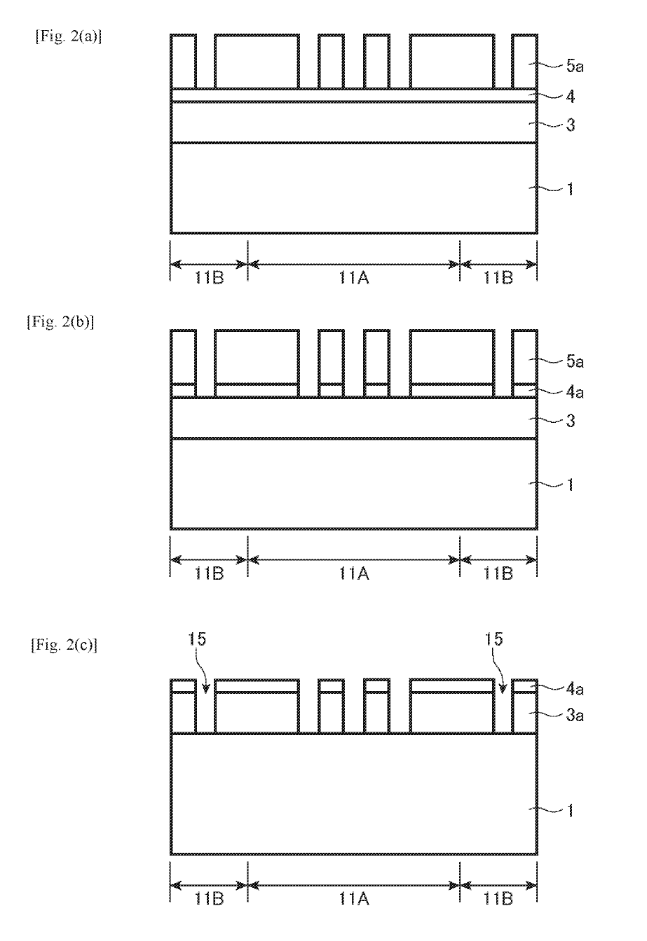

First, a resist film is formed on the hard mask film 4 of the mask blank 100 by spin-coating. Next, a first pattern that is to be a light shielding pattern to be formed on the light shielding film 3 is exposure-drawn with an electron beam on the resist film. In this circumstance, a central portion of the transparent substrate 1 is deemed as a transfer pattern forming region 11A onto which a light shielding pattern forming a part of the transfer pattern is exposure-drawn. Further, an alignment pattern, barcode pattern, etc. is exposure-drawn on an outer peripheral region 11B of the transfer pattern forming region 11A. Thereafter, the resist film is subjected to predetermined treatments such as PEB treatment, developing treatment, and post-baking treatment, and the first pattern (resist pattern 5a) forming alight shielding pattern is formed on the resist film (see FIG. 2(a)).

Incidentally, the dug-down Levenson type phase shift mask explained herein includes a transfer pattern that is constructed from a light shielding pattern and a dug-down pattern (phase shift pattern). Further, electron beam is often used for exposure writing on a resist film.

Next, dry etching of the hard mask film 4 is carried out using fluorine-based gas with the resist pattern 5a as a mask, and a first pattern (hard mask pattern 4a) is formed on the hard mask film 4 (see FIG. 2(b)). Subsequently, the resist pattern 5a is removed. Incidentally, dry etching of the light shielding film 3 can be carried out with the resist pattern 5a remaining. In such a case, the resist pattern 5a is eliminated upon dry etching of the light shielding film 3.

Next, high-bias etching using oxygen-containing chlorine-based gas is carried out using the hard mask pattern 4a as a mask, and a first pattern (light shielding pattern 3a) is formed on the light shielding film 3 (see FIG. 2(c)). In dry etching by oxygen-containing chlorine-based gas on the light shielding film 3, etching gas having a higher mixing ratio of chlorine-based gas is used than conventionally used. The mixing ratio of mixed gas of chlorine-based gas and oxygen gas in dry etching of the light shielding film 3 is, at gas flow ratio in an etching apparatus, preferably chlorine-based gas:oxygen gas=10 or more:1, more preferably 15 or more:1, and further preferably 20 or more:1. By using etching gas with a high mixing ratio of chlorine-based gas, the anisotropic property of dry etching can be enhanced. Further, in dry etching of the light shielding film 3, the mixing ratio of mixed gas of chlorine-based gas and oxygen gas is, at gas flow ratio in an etching chamber, preferably chlorine-based gas:oxygen gas=40 or less:1.

In dry etching of the light shielding film 3 using oxygen-containing chlorine-based gas, bias voltage to be applied from the back side of the transparent substrate 1 is set to be higher than what is conventionally done. Although the effects of increasing the bias voltage vary depending on etching apparatuses, power upon application of the bias voltage is, for example, preferably 15 [W] or more, more preferably 20 [W] or more, and even more preferably 30 [W] or more. By increasing the bias voltage, anisotropic property of dry etching by oxygen-containing chlorine-based gas can be enhanced.

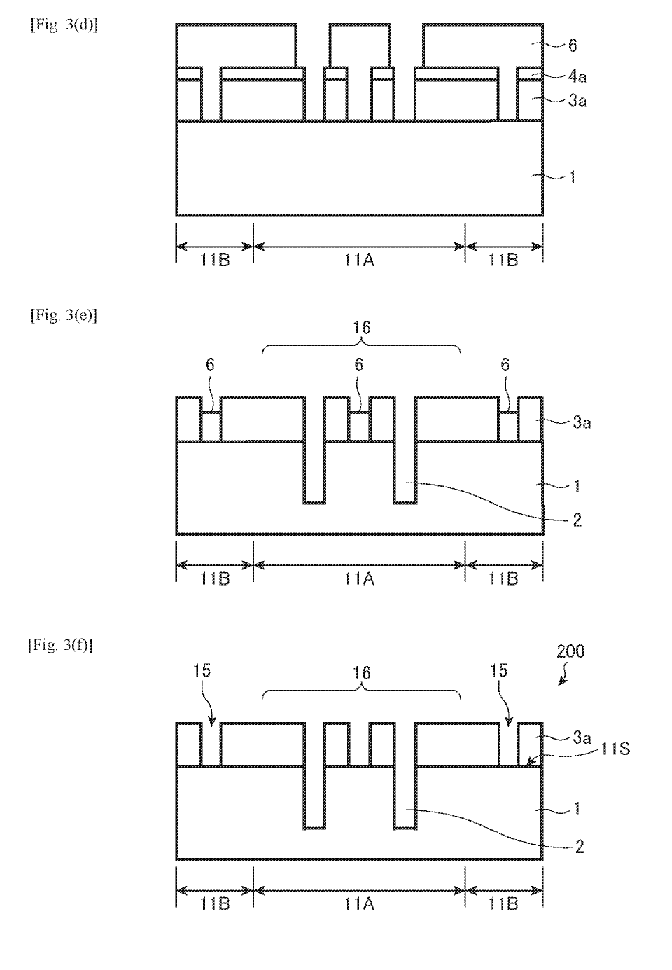

Next, a resist film (second resist film) 6 having a dug-down pattern is formed on the hard mask film 4 (hard mask pattern 4a) having a light shielding pattern formed thereon, as shown in FIG. 3 (d). In this case, a resist film 6 is formed on the transparent substrate 1 by spin coating. Next, exposure writing is carried out on the coated resist film 6 and thereafter predetermined treatments such as a developing treatment are carried out. Through the above process, a dug-down pattern where the transparent substrate 1 is exposed is formed on the resist film 6 of the transfer pattern forming region 11A. Incidentally, the dug-down pattern is formed herein such that the dug-down pattern is formed on the resist film 6 at an opening width with margin of misalignment that occurs during the exposure step, and an opening of the dug-down pattern to be formed on the resist film 6 fully exposes an opening of the light shielding pattern.

Next, dry etching of the transparent substrate 1 is carried out using fluorine-based gas, with the resist film 6 having the dug-down pattern and the light shielding film 3 having the light shielding pattern 3a formed thereon as a mask as shown in FIG. 3 (e). Through the above process, a dug-down pattern 2 is formed on a main surface 11S in the transfer pattern forming region 11A of the transparent substrate 1. The dug-down pattern 2 is formed into a depth such that exposure light transmitting through the dug-down pattern 2 creates a predetermined phase difference (e.g., 150°˜190°) relative to exposure light transmitting through the transparent substrate 1 with no digging on its surface. For example, in the case where ArF excimer laser light is applied as exposure light, the dug-down pattern is formed into a depth of about 173 nm (in the case of 180° phase difference).

Further, the resist film 6 is reduced during this dry etching by fluorine-based gas, and the entire resist film 6 on the hard mask film 4 disappears. Moreover, the hard mask film 4 also disappears through dry etching by fluorine-based gas. Through the above process, a transfer pattern 16 including the light shielding pattern 3a and the dug-down pattern 2 formed on the transparent substrate 1 is formed on the transfer pattern forming region 11A. Thereafter the remaining resist film 6 is removed.

Through the above procedures, a phase shift mask 200 as shown in FIG. 3(f) is obtained. The phase shift mask 200 manufactured through the above procedures has a structure that includes a dug-down pattern 2 on the side of one main surface 11S of the transparent substrate 1, and includes the light shielding film 3 having the light shielding pattern 3a formed thereon provided on the main surface 11S of the transparent substrate 1. The dug-down pattern 2 is formed on the main surface 11S side of the transparent substrate 1 in a continuous manner from the bottom of an opening of the dug-down pattern 2 at the transfer pattern forming region 11A of the transparent substrate 1. Thus, the transfer pattern 16 including the dug-down pattern 2 and the light shielding pattern 3a are arranged on the transfer pattern forming region 11A. Further, the outer peripheral region 11B is provided with an alignment pattern 15 in the shape of a hole penetrating the light shielding film 3.

There is no particular limitation to chlorine-based gas used for dry etching in the above manufacturing step, as long as Cl is included, the chlorine-based gas including, for example, Cl₂, SiCl₂, CHCl₃, CH₂Cl₂, CCl₄, and BCl₃. Further, there is no particular limitation to fluorine-based gas to be used for dry etching in the above manufacturing step, as long as F is included, the fluorine-based gas including, for example, CHF₃, CF₄, C₂F₈, C₄F₈, and SF₈. Particularly, fluorine-based gas free of C can further reduce damage on a glass substrate for having a relatively low etching rate to a glass substrate.

In the manufacturing method of the phase shift mask explained above, the phase shift mask 200 is manufactured using the mask blank 100 explained in FIG. 1. In the manufacture of the phase shift mask described above, dry etching by oxygen-containing chlorine-based gas having tendency of isotropic etching is applied in the step of FIG. 2 (c) which is a dry etching step for forming the light shielding pattern 3a (fine pattern) on the light shielding film 3. Further, dry etching by oxygen-containing chlorine-based gas in the step of FIG. 2 (c) is carried out under an etching condition having higher ratio of chlorine-based gas in the oxygen-containing chlorine-based gas and applying high bias voltage. Thus, in the step of dry etching of the light shielding film 3, a reduction in the etching rate can be suppressed while enhancing the tendency of anisotropic property of etching. Thus, side etching when forming the light shielding pattern 3a on the light shielding film 3 is reduced.

By using the resist film 6 with reduced side etching and having the precisely formed light shielding pattern 3a and the dug-down pattern as an etching mask and dry-etching the transparent substrate 1 with fluorine-based gas, the transfer pattern 16 made of the dug-down pattern 2 and the light shielding pattern 3a can be formed with high precision. Through the above action, the phase shift mask 200 with excellent pattern precision can be manufactured.

### Manufacturing Method of Semiconductor Device

Next, the manufacturing method of a semiconductor device using the phase shift mask 200 manufactured by the above-mentioned manufacturing method is described. The manufacturing method of the semiconductor device is characterized in using the dug-down Levenson type phase shift mask 200 manufactured by the above manufacturing method, and exposure-transferring a transfer pattern of the phase shift mask 200 on a resist film on a substrate. The manufacturing method of the semiconductor device above is carried out as follows.

First, a substrate for forming the semiconductor device is prepared. The substrate can be, for example, a semiconductor substrate, a substrate having a semiconductor thin film, and can further have a fine-processed film formed thereon. A resist film is formed on the prepared substrate, and the resist film is subjected to pattern exposure using the dug-down Levenson type phase shift mask 200 manufactured by the manufacturing method mentioned above. Thus, the transfer pattern formed on the phase shift mask 200 is exposure-transferred to the resist film. On this occasion, ArF excimer laser light is used herein as the exposure light, for example.

Further, the resist film onto which the transfer pattern is exposure-transferred is subjected to developing treatment to form a resist pattern, subjected to etching processing on a surface layer of the substrate using the resist pattern as a mask, treated to introduce impurities, etc. After the completion of the treatments, the resist pattern is removed. The above treatments are repeated on the substrate while replacing the transfer mask, and through further necessary processing, the semiconductor device is completed.

In the manufacture of the semiconductor device as mentioned above, a resist pattern with a precision that sufficiently satisfies initial design specification can be formed on the substrate by using the dug-down Levenson type phase shift mask manufactured by the above-mentioned manufacturing method. Therefore, in the case where a lower layer film below the resist film is dry etched to forma circuit pattern using the pattern of the resist film as a mask, a highly precise circuit pattern without short-circuit of wiring and disconnection caused by insufficient precision can be formed.

### EXAMPLES

The embodiments of this invention are further described concretely below along with examples.

### Example 1

### Manufacture of Mask Blank

In view of FIG. 1, a transparent substrate 1 made of a synthetic quartz glass with a size of a main surface of about 152 mm×about 152 mm and a thickness of about 6.35 mm was prepared. End surface and main surface of the transparent substrate 1 were polished to a predetermined surface roughness (0.2 nm or less root mean square roughness Rq), and thereafter subjected to predetermined cleaning treatment and drying treatment.

Next, the transparent substrate 1 was placed in a single-wafer DC sputtering apparatus, and by reactive sputtering (DC sputtering) using a chromium (Cr) target and with a mixed gas atmosphere of argon (Ar), carbon dioxide (CO₂), and helium (He), a light shielding film (CrOC film) 3 made of chromium, oxygen, and carbon was formed in contact with the transparent substrate 1 at a thickness of 59 nm.

Next, the transparent substrate 1 having the light shielding film (CrOC film) 3 formed thereon was subjected to heat treatment. Concretely, the heat treatment was carried out using a hot plate at a heating temperature of 280° C. in the atmosphere for five minutes. After the heat treatment, a spectrophotometer (Cary4000 manufactured by Agilent Technologies) was used on the transparent substrate 1 having the light shielding film 3 formed thereon to measure optical density of the light shielding film 3 to ArF excimer laser light wavelength (about 193 nm), confirming the value of 3.0 or more.

Next, the transparent substrate 1 having the light shielding film 3 formed thereon was placed in a single-wafer RF sputtering apparatus, and by RF sputtering using silicon dioxide (SiO₂) target and argon (Ar) gas as sputtering gas, a hard mask film 4 made of silicon and oxygen was formed on the light shielding film 3 at a thickness of 12 nm. Further, a predetermined cleaning treatment was carried out to form a mask blank 100 of Example 1.

Another transparent substrate 1 was prepared, which has only the light shielding film 3 formed on its main surface under the same conditions as above, and which was subjected to heat treatment. The light shielding film 3 was analyzed by an X-ray photoelectron spectroscopy: XPS (with RBS correction). As a result, it was confirmed that the region near the surface that is opposite of the transparent substrate 1 side of the light shielding film 3 (region up to about 2 nm depth from the surface) has a composition gradient portion having more oxygen content than other regions (40 atom % or more oxygen content). Further, content of each constituent element in the region of the light shielding film 3 excluding the composition gradient portion was found to be, at an average value, Cr: 71 atom %, O: 15 atom %, and C: 14 atom %. Moreover, it was confirmed that difference of each constituent element in thickness direction of the region of the light shielding film 3 excluding the composition gradient portion is 3 atom % or less, and there is substantially no composition gradient in thickness direction.

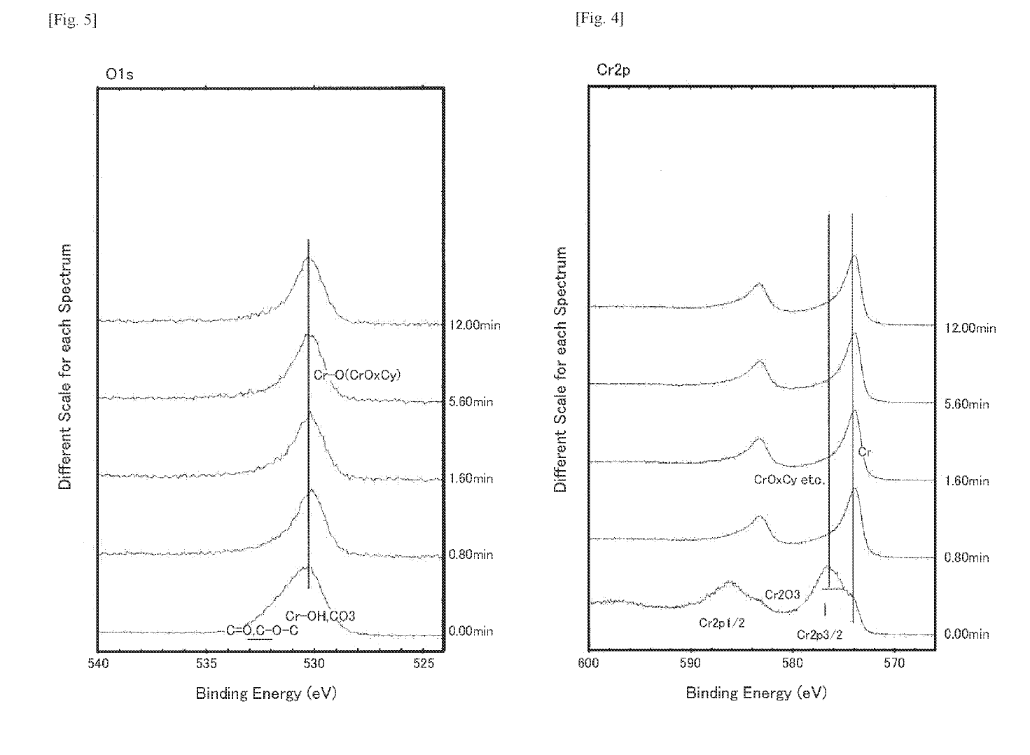

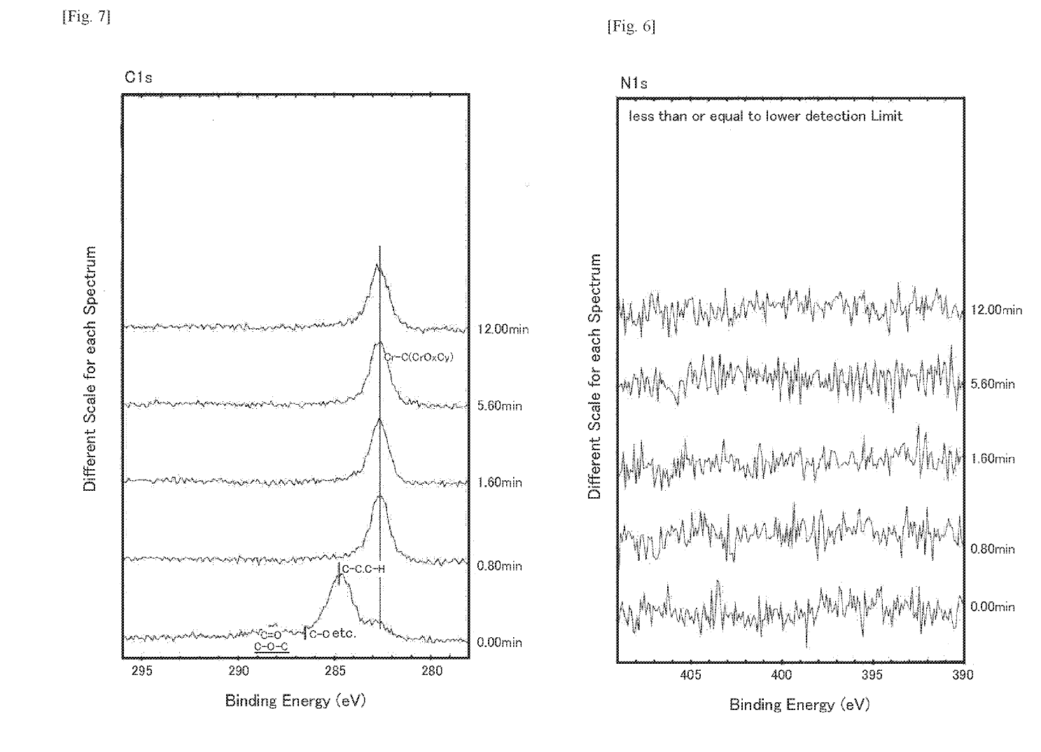

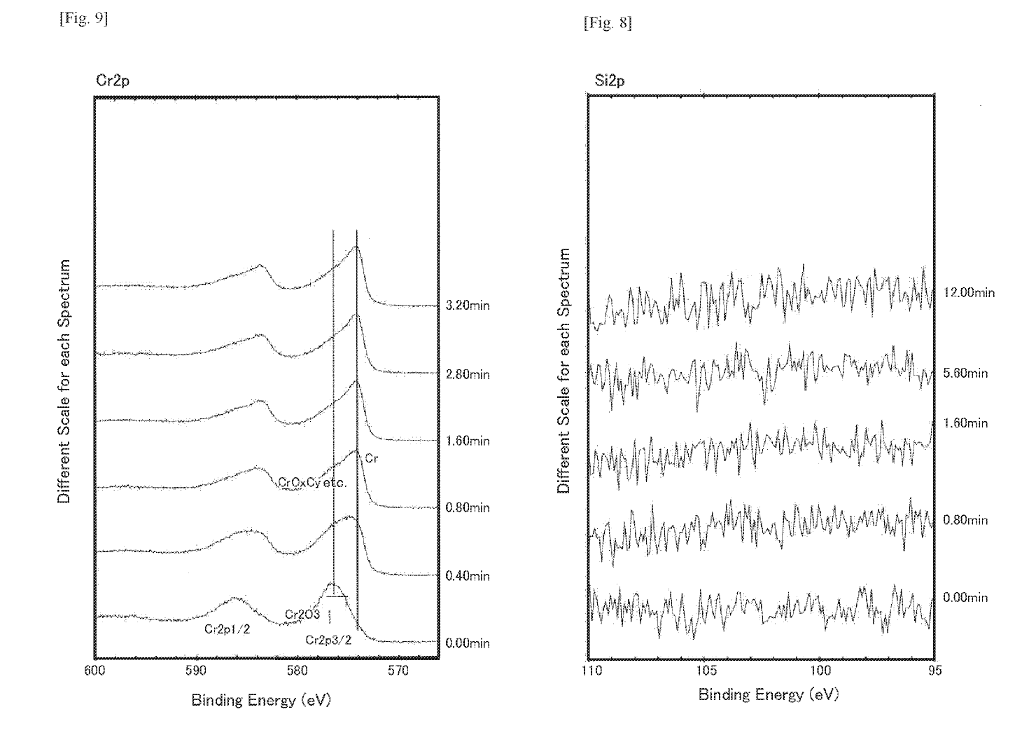

On the result obtained as analysis result by X-ray photoelectron spectroscopy on the light shielding film 3 of Example 1, result of depth direction chemical bonding condition analysis of Cr2p narrow spectrum is shown in FIG. 4, result of depth direction chemical bonding condition analysis of O1s narrow spectrum is shown in FIG. 5, result of depth direction chemical bonding condition analysis of N1s narrow spectrum is shown in FIG. 6, result of depth direction chemical bonding condition analysis of C1s narrow spectrum is shown in FIG. 7, and result of depth direction chemical bonding condition analysis of Si2p narrow spectrum is shown in FIG. 8, respectively.

In the analysis of X-ray photoelectron spectroscopy on the light shielding film 3, steps of irradiating X-ray on the surface of the light shielding film 3 to measure energy distribution of photoelectrons emitted from the light shielding film 3, digging the light shielding film 3 for a predetermined time through Ar gas sputtering, irradiating X-ray on the surface of the light shielding film 3 of the dug region, and measuring the energy distribution of photoelectrons emitted from the light shielding film 3 are repeated to analyze film thickness direction of the light shielding film 3. Incidentally, this analysis of X-ray photoelectron spectroscopy was carried out using monochromatized Al (1486.6 eV) as an X-ray source, under the conditions of 100 μmφ photoelectron detection area and about 4-5 nm detection depth (take-off angle 45 deg) (the same applies to other Examples and Comparative Examples hereinafter).

In each depth direction the chemical bonding condition analysis in FIG. 4 to FIG. 8, “0.00 min plot” shows the analysis result of an uppermost surface of the light shielding film 3 before Ar gas sputtering (sputtering time: 0 min), “0.80 min plot” shows the analysis result at a position in film thickness direction of the light shielding film 3 after an uppermost surface of the light shielding film 3 was dug only for 0.80 min by Ar gas sputtering, “1.60 min plot” shows the analysis result at a position in film thickness direction of the light shielding film 3 after an uppermost surface of the light shielding film 3 was dug only for 1.60 min by Ar gas sputtering, “5.60 min plot” shows the analysis result at a position in film thickness direction of the light shielding film 3 after an uppermost surface of the light shielding film 3 was dug only for 5.60 min by Ar gas sputtering, and “12.00 min plot” shows the analysis result at a position in film thickness direction of the light shielding film 3 after an uppermost surface of the light shielding film 3 was dug only for 12.00 min by Ar gas sputtering.

Incidentally, the position in film thickness direction of the light shielding film 3 after an uppermost surface of the light shielding film 3 was dug only for 0.80 min by Ar gas sputtering is the position deeper than the composition gradient portion. Namely, all plots of the positions of depth of “0.80 min plot” and thereafter are measured results of the portion of the light shielding film 3 excluding the composition gradient portion.

The result of Cr2p narrow spectrum in FIG. 4 proves that the light shielding film 3 of Example 1 has a maximum peak at 574 eV binding energy, except for the uppermost surface (0.00 min plot). This result indicates the existence of chromium atoms that are not bonded to atoms such as nitrogen and oxygen at or more than a certain ratio.

The result of O1s narrow spectrum of FIG. 5 proves that the light shielding film 3 of Example 1 has a maximum peak at about 530 eV binding energy, except for the uppermost surface (0.00 min plot). This result indicates the existence of Cr—O bond at or more than a certain ratio.

The result of N1s narrow spectrum of FIG. 6 proves that the light shielding film 3 of Example 1 has a maximum peak of lower detection limit or less in all depth regions. The result indicates that abundance ratio of atoms bonded to nitrogen, including Cr—N bond, was not detected in the light shielding film 3.

The result of C1s narrow spectrum of FIG. 7 proves that the light shielding film 3 of Example 1 has a maximum peak at 282˜283 eV binding energy, except for the uppermost surface (0.00 min plot). This result indicates the existence of Cr—C bond at or more than a certain ratio.

The result of Si2p narrow spectrum of FIG. 8 proves that the light shielding film 3 of Example 1 has a maximum peak of lower detection limit or less in all depth regions. The result indicates that abundance ratio of atoms bonded to silicon, including Cr—Si bond, was not detected in the light shielding film 3.

Incidentally, the scales of the vertical axis of the graph in each narrow spectrum of FIG. 4 to FIG. 8 are not similar. N1s narrow spectrum of FIG. 6 and Si2p narrow spectrum of FIG. 8 have enlarged vertical axis scale compared to each narrow spectrum of FIG. 4, FIG. 5, and FIG. 7. Oscillation waves in the graph of N1s narrow spectrum of FIG. 6 and Si2p narrow spectrum of FIG. 8 do not represent the presence of peaks, but only represent the appearance of noise.

### Manufacture of Phase Shift Mask

Next, a dug-down Levenson type phase shift mask 200 of Example 1 was manufactured through the following procedure using the mask blank 100 of Example 1. First, a surface of the hard mask film 4 was subjected to HMDS treatment. Subsequently, a resist film of a chemically amplified resist for electron beam writing was formed in contact with the surface of the hard mask film 4 by spin coating at a film thickness of 80 nm. Next, a first pattern, which is a light shielding pattern to be formed on the hard mask film 4, was drawn on the resist film with electron beam, predetermined developing and cleaning treatments were conducted, and a resist pattern 5a having the first pattern was formed (see FIG. 2(a)). The first pattern was formed to include a line-and-space pattern having a line width of 100 nm.

Next, dry etching was conducted using CF₄ gas with the resist pattern 5a as a mask, and a first pattern (hard mask pattern 4a) was formed on the hard mask film 4 (see FIG. 2(b)). Length measurement of space width was made on the formed hard mask pattern 4a at the region where the line-and-space pattern is formed, using a length measurement SEM (CD-SEM: Critical Dimension-Scanning Electron Microscope).

Next, the resist pattern 5a was removed. Subsequently, dry etching (high-bias etching where power when bias voltage was applied is 50 [W]) using a mixed gas of chlorine gas (Cl₂) and oxygen gas (O₂) (gas flow ratio Cl₂:O₂=13:1) was conducted with the hard mask pattern 4a as a mask, and a first pattern (light shielding pattern 3a) was formed on the light shielding film 3 (see FIG. 2 (c)). Incidentally, the time applied as an etching time of the light shielding film 3 (total etching time) is 1.5 times from the initiation of etching of the light shielding film 3 until the surface of the transparent substrate 1 first appears (just etching time). Namely, over etching was carried out with an addition of only 50% of the just etching time (over etching time). By carrying out the over etching, verticality of the pattern side wall of the light shielding film 3 can be enhanced.

Next, a resist film (a second resist film) 6 having a dug-down pattern formed thereon was formed on the hard mask film 4 (hard mask pattern 4a) having a light shielding pattern formed thereon was formed, as shown in FIG. 3 (d). Concretely, a chemically amplified resist for electron beam writing (PRL009: manufactured by FUJIFILM Electronic Materials Co., Ltd.) was formed in contact with the surface of the hard mask film 4 by spin coating with a film thickness of 50 nm. Incidentally, the film thickness of the resist film 6 is the film thickness on the hard mask film 4. Subsequently, a dug-down pattern was drawn by electron beam on the resist film 6, predetermined development treatment and cleaning treatment of the resist film 6 were carried out, and the resist film 6 having a dug-down pattern was formed. On this occasion, the dug-down pattern was formed on the resist film 6 at an opening width with margin of misalignment that occurs during the exposure step, such that the opening of the dug-down pattern formed in the resist film 6 fully exposes the opening of the light shielding pattern 3a.

Subsequently, dry etching of the transparent substrate 1 was carried out using fluorine-based gas (CF₄) with the resist film 6 having the dug-down pattern as a mask, as shown in FIG. 3(e). Thus, the dug-down pattern 2 was formed at a depth of 173 nm on the transfer pattern forming region 11A on the side of one main surface 11S of the transparent substrate 1. The resist film 6 reduced during the dry etching by fluorine-based gas, and the entire resist film 6 on the hard mask film 4 disappeared upon completion of dry etching. Moreover, the hard mask film 4 also disappeared through dry etching by fluorine-based gas. As shown in FIG. 3(f), the remaining resist film 6 was removed, cleaning treatment, etc. were made, and a phase shift mask 200 was obtained.

Length measurement of space width was carried out on the formed light shielding pattern 3a in the region where the line-and-space pattern is formed using a length measurement SEM (CD-SEM: Critical Dimension-Scanning Electron Microscope). Thereafter, etching bias, which is the change amount between the previously-measured space width of the hard mask pattern 4a and the space width of the light shielding pattern 3a, was calculated for each of the plurality of locations in the region where the same line-and-space pattern is formed, and further, average value of etching bias was calculated. As a result, the average value of etching bias was about 6 nm, which was significantly less than conventional value. This shows that even if the light shielding film 3 is patterned through high-bias etching using the hard mask pattern 4a having a fine transfer pattern that should be formed on the light shielding film 3 as an etching mask, the fine light shielding pattern can be formed on the light shielding film 3 at high precision.

### Evaluation of Pattern Transfer Performance

On the phase shift mask 200 manufactured by the above procedures, a simulation of a transfer image was made when an exposure transfer was made on a resist film on a semiconductor device using AIMS193 (manufactured by Carl Zeiss) at an exposure light of 193 nm wavelength. The simulated exposure transfer image was inspected, and the design specification was fully satisfied. It can be considered from this result that a circuit pattern to be finally formed on the semiconductor device can be formed at a high precision, even if the phase shift mask 200 of Example 1 was set on a mask stage of an exposure apparatus and a resist film on the semiconductor device was subjected to exposure transfer.

### Example 2

### Manufacture of Mask Blank

A mask blank 100 of Example 2 was manufactured by the same process as Example 1 except for the light shielding film 3. The light shielding film 3 of Example 2 has film forming conditions that are different from the light shielding film 3 of Example 1. Concretely, a transparent substrate 1 was placed in a single-wafer DC sputtering apparatus, and reactive sputtering (DC sputtering) was carried out using a chromium (Cr) target under mixed gas atmosphere of argon (Ar), carbon dioxide (CO₂), and helium (He). Thus, a light shielding film (CrOC film) 3 made of chromium, oxygen, and carbon was formed at a film thickness of 72 nm in contact with the transparent substrate 1.

Next, the transparent substrate 1 having the light shielding film (CrOC film) 3 formed thereon was subjected to heat treatment with the same conditions as Example 1. After the heat treatment, a spectrophotometer (Cary4000 manufactured by Agilent Technologies) was used on the transparent substrate 1 having the light shielding film 3 formed thereon to measure optical density of the light shielding film 3 to ArF excimer laser light wavelength (about 193 nm), confirming the value of 3.0 or more.

Another transparent substrate 1 was prepared, which has only the light shielding film 3 formed on its main surface under the same conditions as above, and which was subjected to heat treatment. The light shielding film 3 was analyzed by an X-ray photoelectron spectroscopy: XPS (with RBS correction). As a result, it was confirmed that the region near the surface that is opposite the transparent substrate 1 side of the light shielding film 3 (region up to about 2 nm depth from the surface) has a composition gradient portion having more oxygen content than other regions (40 atom % or more oxygen content). Further, content of each constituent element in the region of the light shielding film 3 excluding the composition gradient portion was found to be, at an average value, Cr: 55 atom %, O: 30 atom %, and C: 15 atom %. Moreover, it was confirmed that the difference of each constituent element in thickness direction of the region of the light shielding film 3 excluding the composition gradient portion is 3 atom % or less, and there is substantially no composition gradient in thickness direction.

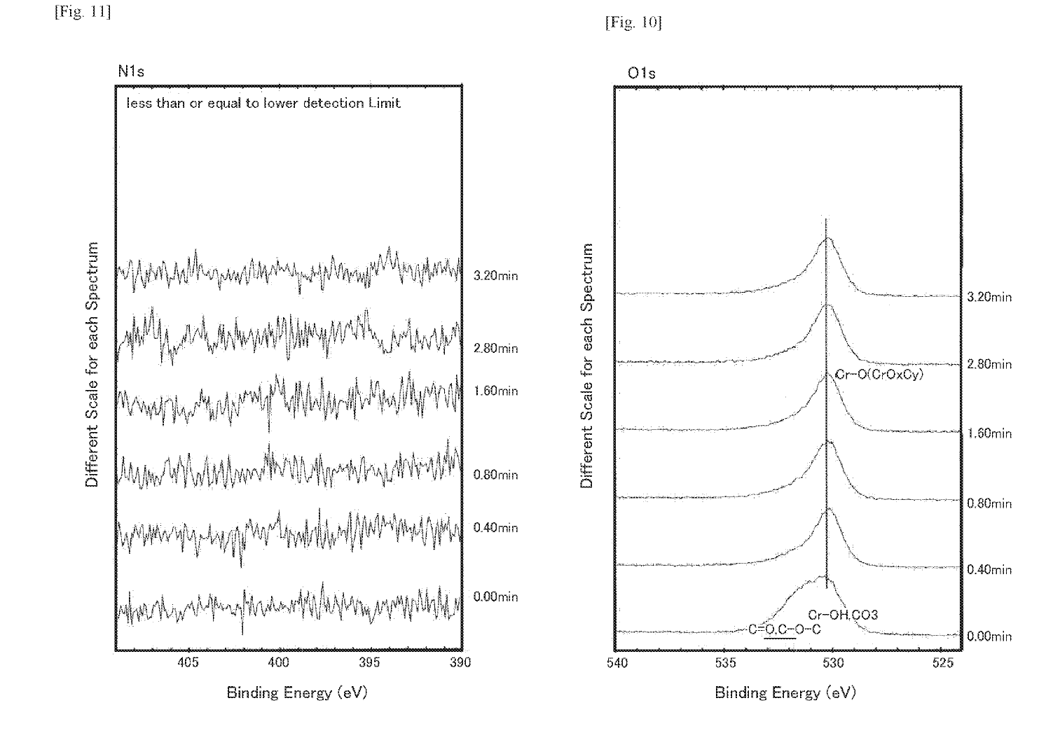

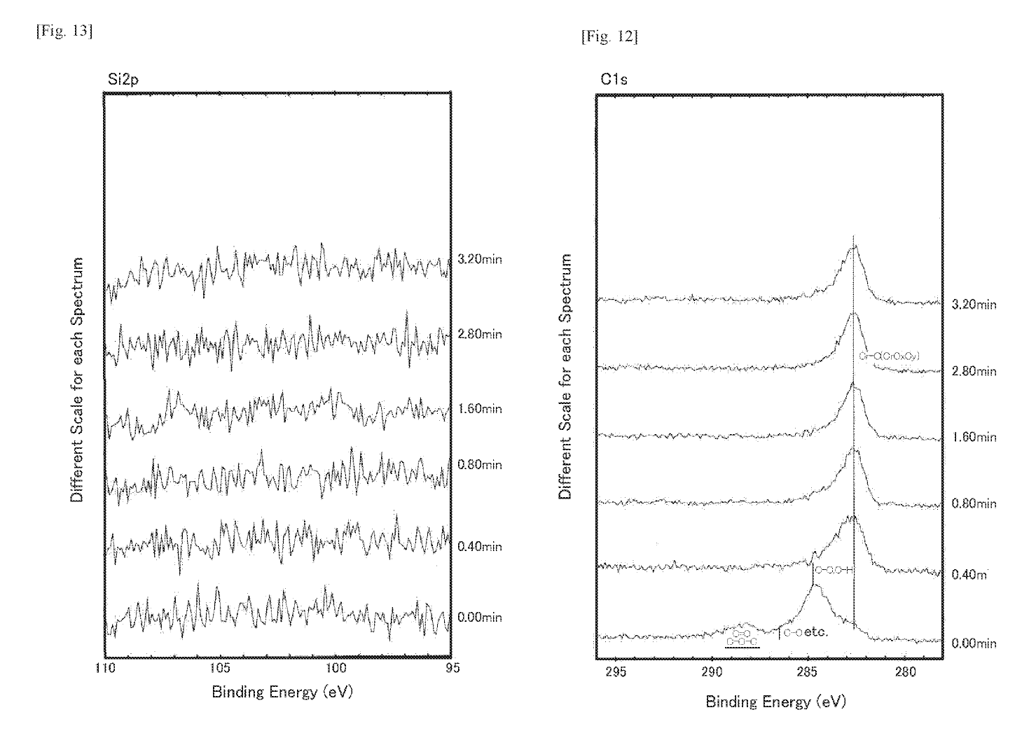

Further, similar to the case of Example 1, the result of depth direction chemical bonding condition analysis of Cr2p narrow spectrum (see FIG. 9), result of depth direction chemical bonding condition analysis of O1s narrow spectrum (see FIG. 10), result of depth direction chemical bonding condition analysis of N1s narrow spectrum (see FIG. 11), the result of depth direction chemical bonding condition analysis of C1s narrow spectrum (see FIG. 12), and the result of depth direction chemical bonding condition analysis of Si2p narrow spectrum (see FIG. 13) were each obtained for the light shielding film 3 of Example 2.

In each depth direction the chemical bonding condition analysis in FIG. 9 to FIG. 13, “0.00 min plot” shows the analysis result of an uppermost surface of the light shielding film 3 before Ar gas sputtering (sputtering time: 0 min), “0.40 min plot” shows analysis result at a position in film thickness direction of the light shielding film 3 after an uppermost surface of the light shielding film 3 was dug only for 0.40 min by Ar gas sputtering, “0.80 min plot” shows the analysis result at a position in film thickness direction of the light shielding film 3 after an uppermost surface of the light shielding film 3 was dug for only 0.80 min by Ar gas sputtering, “1.60 min plot” shows the analysis result at a position in film thickness direction of the light shielding film 3 after an uppermost surface of the light shielding film 3 was dug only for 1.60 min by Ar gas sputtering, “2.80 min plot” shows the analysis result at a position in film thickness direction of the light shielding film 3 after an uppermost surface of the light shielding film 3 was dug only for 2.80 min by Ar gas sputtering, and “3.20 min plot” shows the analysis result at a position in film thickness direction of the light shielding film 3 after an uppermost surface of the light shielding film 3 was dug only for 3.20 min by Ar gas sputtering.

Incidentally, the position in film thickness direction of the light shielding film 3 after an uppermost surface of the light shielding film 3 was dug only for 0.80 min by Ar gas sputtering is a position deeper than the composition gradient portion. Namely, all of the plots of the position of depth of “0.80 min plot” and thereafter are measurement results of the portion of the light shielding film 3 excluding the composition gradient portion.

The result of Cr2p narrow spectrum of FIG. 9 proves that the light shielding film 3 of Example 2 has a maximum peak at binding energy of 574 eV in the region of depth of “0.80 min plot” and thereafter. This result indicates the existence of chromium atoms that are not bonded to atoms such as nitrogen and oxygen at or more than a certain ratio.

The result of O1s narrow spectrum of FIG. 10 proves that the light shielding film 3 of Example 2 has a maximum peak at about 530 eV binding energy in the region of depth of “0.80 min plot” and thereafter. This result indicates the existence of Cr—O bond at or more than a certain ratio.

The result of N1s narrow spectrum of FIG. 11 proves that the light shielding film 3 of Example 2 has a maximum peak of lower detection limit or less in all depth regions. The result indicates that abundance ratio of atoms bonded to nitrogen, including Cr—N bond, was not detected in the light shielding film 3.

The result of C1s narrow spectrum of FIG. 12 proves that the light shielding film 3 of Example 2 has a maximum peak at 282˜283 eV binding energy in the region of depth of “0.80 min plot” and thereafter. This result indicates the existence of Cr—C bond at or more than a certain ratio.

The result of Si2p narrow spectrum of FIG. 13 proves that the light shielding film 3 of Example 2 has a maximum peak of lower detection limit or less in all depth regions. The result indicates that abundance ratio of atoms bonded to silicon, including Cr—Si bond, was not detected in the light shielding film 3.

Incidentally, the scales of the vertical axis of the graph in each narrow spectrum of FIG. 9 to FIG. 13 are not similar. N1s narrow spectrum of FIG. 11 and Si2p narrow spectrum of FIG. 13 have enlarged vertical axis scale compared to each narrow spectrum of FIG. 9, FIG. 10, and FIG. 12. Oscillation waves in the graph of N1s narrow spectrum of FIG. 11 and Si2p narrow spectrum of FIG. 13 do not represent the presence of peaks, but only represent the appearance of noise.

### Manufacture of Phase Shift Mask

Next, a phase shift mask 200 of Example 2 was manufactured using the mask blank 100 of Example 2 through the procedure similar to Example 1. Similar to the case of Example 1, length measurement of space width was carried out on the region where the line-and-space pattern is formed after the hard mask pattern 4a was formed (see FIG. 2(b)) and after the light shielding pattern 3a was formed (see FIG. 3(f)), respectively, using a length measurement SEM (CD-SEM: Critical Dimension-Scanning Electron Microscope). Thereafter, etching bias, which is the change amount between the space width of the hard mask pattern 4a and the space width of the light shielding pattern 3a, was calculated for each of the plurality of locations in the region where the same line-and-space pattern is formed, and further, the average value of etching bias was calculated. As a result, the average value of etching bias was about 10 nm, which was sufficiently less than conventional value. This shows that in the mask blank 100 of Example 2, even if the light shielding film 3 is patterned through high-bias etching using the hard mask pattern 4a having a fine transfer pattern that should be formed on the light shielding film 3 as an etching mask, the fine transfer pattern can be formed on the light shielding film 3 at high precision.

### Evaluation of Pattern Transfer Performance

On the phase shift mask 200 of Example 2, a simulation of a transfer image was made when an exposure transfer was made on a resist film on a semiconductor device using AIMS193 (manufactured by Carl Zeiss) at an exposure light of wavelength 193 nm, similar to Example 1. The exposure transfer image of this simulation was verified, and the design specification was sufficiently satisfied. It can be considered from this result that a circuit pattern to be finally formed on the semiconductor device can be formed at a high precision, even if the phase shift mask 200 of Example 2 was set on a mask stage of an exposure apparatus and a resist film on the semiconductor device was subjected to exposure transfer.

### Comparative Example 1

### Manufacture of Mask Blank

A mask blank of Comparative Example 1 was manufactured by the same process as Example 1, except for the light shielding film. A light shielding film of Comparative Example 1 has film forming conditions that are different than the light shielding film 3 of Example 1. Concretely, a transparent substrate was placed in a single-wafer DC sputtering apparatus, and reactive sputtering (DC sputtering) was carried out using chromium (Cr) target under mixed gas atmosphere of argon (Ar), carbon dioxide (CO₂), nitrogen (N₂), and helium (He). Thus, a light shielding film (CrOCN film) made of chromium, oxygen, carbon, and nitrogen was formed at a film thickness of 72 nm in contact with the transparent substrate.

Next, the transparent substrate having the light shielding film (CrOCN film) formed thereon was subjected to heat treatment under the same conditions as Example 1. After the heat treatment, a spectrophotometer (Cary4000 manufactured by Agilent Technologies) was used on the transparent substrate having the light shielding film formed thereon to measure optical density of the structure of the light shielding film under ArF excimer laser light wavelength (about 193 nm), confirming the optical density of 3.0 or more.

Another transparent substrate was prepared, which has only a light shielding film formed on its main surface under the same conditions as above, and which was subjected to heat treatment. The light shielding film was analyzed by an X-ray photoelectron spectroscopy: XPS (with RBS correction). As a result, it was confirmed that the region near the surface that is opposite of the transparent substrate side of the light shielding film (region up to about 2 nm depth from the surface) has a composition gradient portion having more oxygen content than other regions (40 atom % or more oxygen content). Further, the content of each constituent element in the region of the light shielding film excluding the composition gradient portion was found to be, at an average value, Cr: 55 atom %, O: 22 atom %, C: 12 atom %, and N: 11 atom %. Moreover, it was confirmed that the difference of each constituent element in thickness direction of the region of the light shielding film excluding the composition gradient portion is 3 atom % or less, and there is substantially no composition gradient in thickness direction.

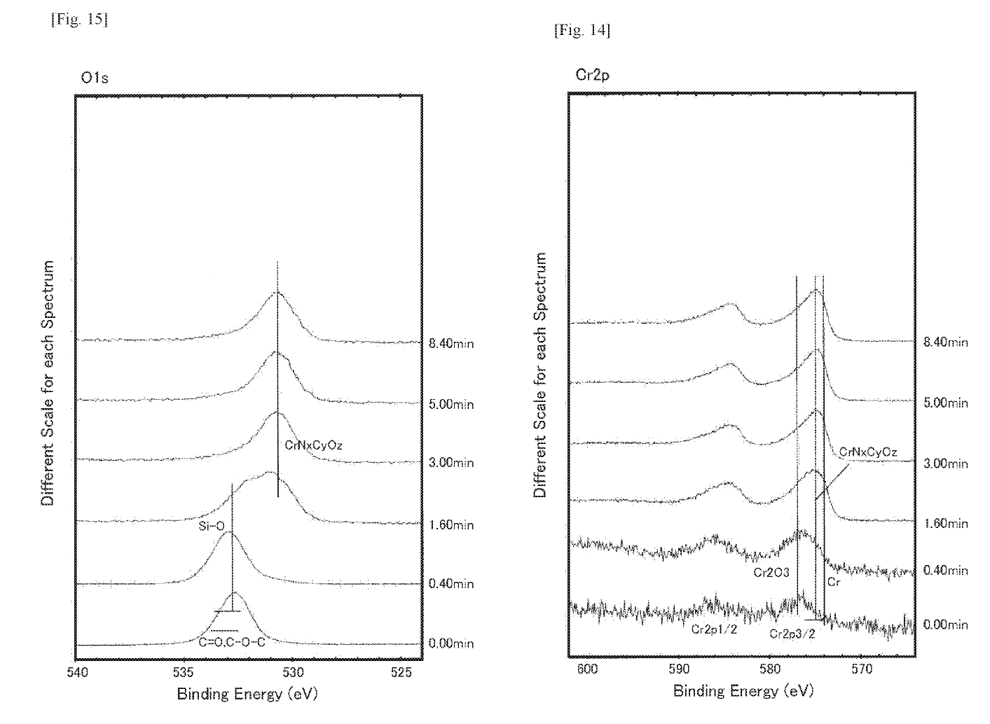

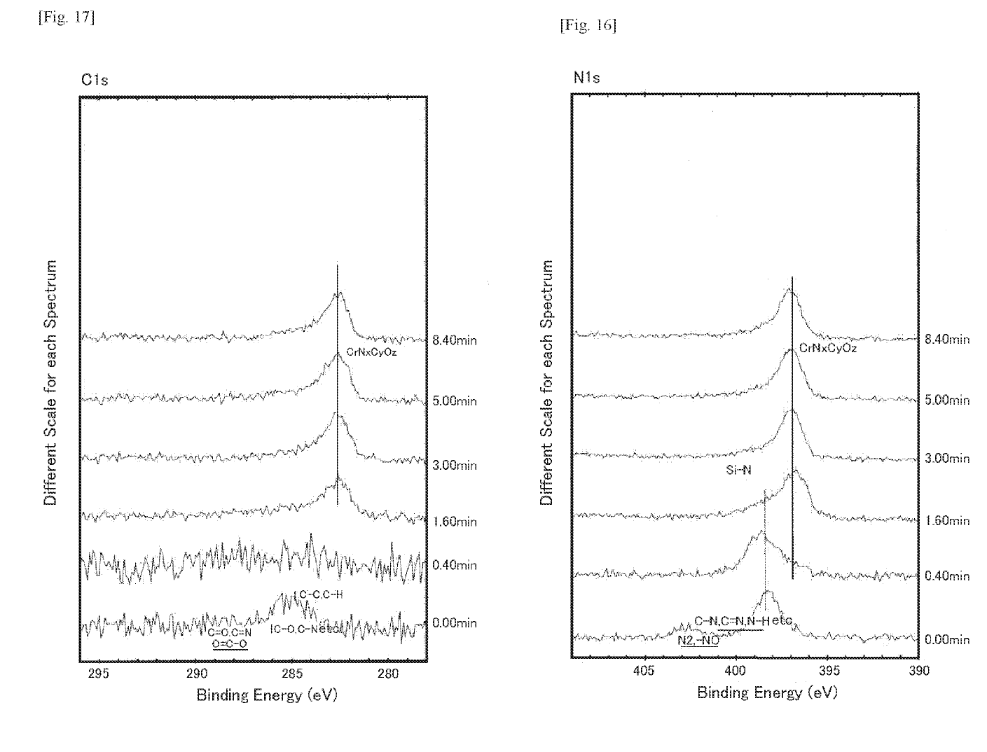

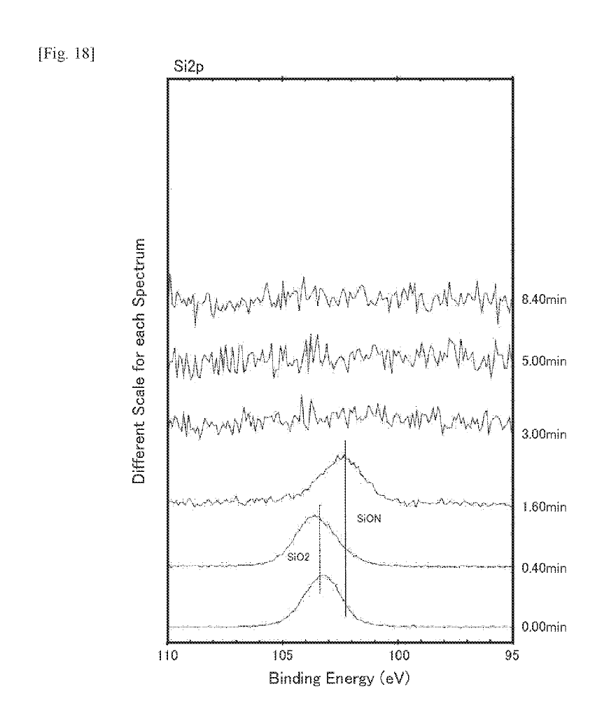

Another transparent substrate was prepared, which has only a light shielding film formed on its main surface under the same conditions as above, which was subjected to heat treatment, and further, a hard mask film was formed in contact with a surface of the light shielding film after the heat treatment. On the hard mask film and the light shielding film of Comparative Example 1, result of depth direction chemical bonding condition analysis of Cr2p narrow spectrum (see FIG. 14), result of depth direction chemical bonding condition analysis of O1s narrow spectrum (see FIG. 15), result of depth direction chemical bonding condition analysis of N1s narrow spectrum (see FIG. 16), result of depth direction chemical bonding condition analysis of C1s narrow spectrum (see FIG. 17), and result of depth direction chemical bonding condition analysis of Si2p narrow spectrum (see FIG. 18) were each obtained under the measurement conditions similar to the case of Example 1.

In each depth direction chemical bonding condition analysis in FIG. 14 to FIG. 18, “0.00 min plot” shows the analysis result of a hard mask film before Ar gas sputtering (sputtering time: 0 min), “0.40 min plot” shows the analysis result at a position dug from an uppermost surface of a hard mask film only for 0.40 min by Ar gas sputtering, “1.60 min plot” shows the analysis result at a position dug from an uppermost surface of a hard mask film only for 1.60 min by Ar gas sputtering, “3.00 min plot” shows analysis result at a position dug from an uppermost surface of a hard mask film only for 3.00 min by Ar gas sputtering, “5.00 min plot” shows the analysis result at a position dug from an uppermost surface of a hard mask film only for 5.00 min by Ar gas sputtering, and “8.40 min plot” shows the analysis result at a position dug from an uppermost surface of a hard mask film for only 8.40 min by Ar gas sputtering.

Incidentally, the position dug from an uppermost surface of a hard mask film only for 1.60 min by Ar gas sputtering is the interior of the light shielding film, and is a position deeper than the composition gradient portion. Namely, all of the plots of the positions of “1.60 min plot” and thereafter are measurement results of portion of the light shielding film excluding the composition gradient portion of Comparative Example 1.

The result of Cr2p narrow spectrum of FIG. 14 proves that the light shielding film of Comparative Example 1 has a maximum peak at binding energy greater than 574 eV in the region of depth of “1.60 min plot” and thereafter. This result can be considered as under so-called chemical shift, indicating that abundance ratio of chromium atoms that are bonded to atoms such as nitrogen and oxygen is significantly low.

The result of O1s narrow spectrum in FIG. 15 proves that the light shielding film of Comparative Example 1 has a maximum peak at about 530 eV binding energy in the region of depth of “1.60 min plot” and thereafter. This result indicates the existence of Cr—O bond at a certain ratio or more.

The result of N1s narrow spectrum in FIG. 16 proves that the light shielding film of Comparative Example 1 has a maximum peak at about 397 eV binding energy in the region of depth of “1.60 min plot” and thereafter. This result indicates the existence of Cr—N bond at a certain ratio or more.

The result of C1s narrow spectrum in FIG. 17 proves that the light shielding film of Comparative Example 1 has a maximum peak at 283 eV binding energy in the region of depth of “1.60 min plot” and thereafter. This result indicates the existence of Cr—C bond at a certain ratio or more.

The result of Si2p narrow spectrum in FIG. 18 proves that the light shielding film of Comparative Example 1 has a maximum peak that is at or below lower detection limit in the region of depth of “1.60 min plot” and thereafter. The result indicates that abundance ratio of atoms bonded to silicon, including Cr—Si bond, was not detected in the light shielding film of Comparative Example 1.

### Manufacture of Phase Shift Mask

Next, a phase shift mask of Comparative Example 1 was manufactured using the mask blank of Comparative Example 1 through the procedure similar to Example 1.

Similar to the case of Example 1, length measurement of space width was carried out in the region where the line-and-space pattern is formed after the hard mask pattern was formed (see FIG. 2 (b)) and after the transfer pattern was formed (see FIG. 3(f)), respectively, using a length measurement SEM (CD-SEM: Critical Dimension-Scanning Electron Microscope). Thereafter, etching bias, which is the change amount between the space width of the hard mask pattern and the space width of the light shielding pattern of the manufactured phase shift mask was calculated for each of the plurality of locations in the region where the same line-and-space pattern is formed, and further, the average value of etching bias was calculated. As a result, the average value of etching bias was 20 nm, which was a rather great value. This indicates that in the case where a light shielding film was patterned through high-bias etching using a hard mask pattern having a fine transfer pattern that should be formed on a light shielding film as an etching mask in the mask blank of Comparative Example 1, it is difficult to form the fine transfer pattern precisely on the light shielding film.

### Evaluation of Pattern Transfer Performance

On the phase shift mask of Comparative Example 1, a simulation of a transfer image was made when an exposure transfer was made on a resist film on a semiconductor device using AIMS193 (manufactured by Carl Zeiss) at an exposure light of wavelength 193 nm, similar to Example 1. The exposure transfer image of this simulation was verified, and a transfer defect was confirmed. Generation factor of the transfer defect is inferred as poor verticality of the shape caused by a large side etching amount in the pattern side wall of the light shielding pattern, and moreover, low in-plane CD uniformity. From this result, it can be considered that when the phase shift mask of Comparative Example 1 was set on a mask stage of an exposure apparatus and exposure-transferred to a resist film on a semiconductor device, a defected area will generate on a circuit pattern to be finally formed on the semiconductor device.

### Comparative Example 2

### Manufacture of Mask Blank

A mask blank of Comparative Example 2 was manufactured by the same process as Example 1, except for the light shielding film. A light shielding film of Comparative Example 2 has a different film forming condition from the light shielding film 3 of Example 1. Concretely, a transparent substrate was placed in a single-wafer DC sputtering apparatus, and reactive sputtering (DC sputtering) was carried out using a chromium (Cr) target under mixed gas atmosphere of argon (Ar), nitrogen monoxide (NO), and helium (He). Thus, a light shielding film (CrON film) made of chromium, oxygen, and nitrogen was formed at a film thickness of 72 nm in contact with the transparent substrate.

Next, the transparent substrate having the light shielding film (CrON film) formed thereon was subjected to heat treatment with the same conditions as Example 1. After the heat treatment, a spectrophotometer (Cary4000 manufactured by Agilent Technologies) was used on the transparent substrate having the light shielding film formed thereon to measure optical density of the light shielding film of the stacked structure under ArF excimer laser light wavelength (about 193 nm), and the optical density was 3.0 or more.

Another transparent substrate was prepared, which has only a light shielding film formed on its main surface under the same conditions as above, and which was subjected to heat treatment. The light shielding film was analyzed by an X-ray photoelectron spectroscopy: XPS (with RBS correction). As a result, it was confirmed that the region near the surface that is opposite of the transparent substrate 1 side of the light shielding film (region up to about 2 nm depth from the surface) has a composition gradient portion having more oxygen content than other regions (40 atom % or more oxygen content). Further, content of each constituent element in the region of the light shielding film excluding the composition gradient portion was found to be, at an average value, Cr: 58 atom %, O: 17 atom %, and N: 25 atom %. Moreover, it was confirmed that the difference of each constituent element in thickness direction of the region of the light shielding film excluding the composition gradient portion is 3 atom % or less, and there is substantially no composition gradient in thickness direction.

Similar to the case of Example 1, result of depth direction chemical bonding condition analysis of Cr2p narrow spectrum, the result of depth direction chemical bonding condition analysis of O1s narrow spectrum, the result of depth direction chemical bonding condition analysis of N1s narrow spectrum, the result of depth direction chemical bonding condition analysis of C1s narrow spectrum, and the result of depth direction chemical bonding condition analysis of Si2p narrow spectrum were each obtained also for the light shielding film of Comparative Example 2.

The result of Cr2p narrow spectrum proves that the light shielding film of Comparative Example 2 has a maximum peak at binding energy greater than 574 eV at all depth regions including the uppermost surface. This result can be regarded as a so-called chemical shift, indicating that abundance ratio of chromium atoms that are bonded to atoms such as nitrogen and oxygen is significantly low. From the result of O1s narrow spectrum, it was found that the light shielding film of Comparative Example 2 has a maximum peak at binding energy of about 530 eV at all depth regions including the uppermost surface. The result indicates that Cr—O bond is present at or more than a certain ratio.

The result of N1s narrow spectrum proves, excluding the uppermost surface, as having a maximum peak at binding energy of about 397 eV. This result indicates that Cr—N bond is present at or more than a certain ratio.

The result of C1s narrow spectrum proves that the light shielding film of Comparative Example 2 has a maximum peak of lower detection limit or less, excluding the uppermost surface. Moreover, since the uppermost surface is significantly subjected to effects of contamination such as organic matters, the measured result on carbon is hardly used as a reference for the uppermost surface. The result indicates that the abundance ratio of atoms bonded to carbon, including Cr—C bond, was not detected in the light shielding film of Comparative Example 2.

The result of Si2p narrow spectrum proves that the light shielding film of Comparative Example 2 has a maximum peak of lower detection limit or less at all depth regions. The result indicates that abundance ratio of atoms bonded to silicon, including Cr—Si bond, was not detected in the light shielding film of Comparative Example 2.

### Manufacture of Phase Shift Mask

Next, a phase shift mask of Comparative Example 2 was manufactured using the mask blank of Comparative Example 2 through the procedure similar to Example 1. Similar to the case of Example 2, length measurement of space width was carried out in the region where the line-and-space pattern is formed after the hard mask pattern was formed (see FIG. 2 (b)) and after the transfer pattern was formed (see FIG. 3 (f)), respectively, using a length measurement SEM (CD-SEM: Critical Dimension-Scanning Electron Microscope). Thereafter, etching bias, which is the change amount between the space width of the hard mask pattern and the space width of the light shielding pattern of the manufactured phase shift mask, was calculated for each of the plurality of locations in the region where the same line-and-space pattern is formed, and further, the average value of etching bias was calculated. As a result, the average value of etching bias was 30 nm, which was a significantly great value. This indicates that in the case where alight shielding film was patterned through high-bias etching using a hard mask pattern having a fine transfer pattern that should be formed on a light shielding film as an etching mask in the mask blank of Comparative Example 2, it is difficult to form the fine transfer pattern precisely on the light shielding film.

### Evaluation of Pattern Transfer Performance

On the phase shift mask of Comparative Example 2, a simulation of a transfer image was made when an exposure transfer was made on a resist film on a semiconductor device using AIMS193 (manufactured by Carl Zeiss) at an exposure light of wavelength 193 nm, similar to Example 1. The exposure transfer image of this simulation was verified, and a transfer defect was confirmed. The generation factor of the transfer defect is inferred as poor verticality of the shape caused by large side etching amount in the pattern side wall of the light shielding pattern, and moreover, low in-plane CD uniformity. From this result, it can be considered that when the phase shift mask of Comparative Example 2 was set on a mask stage of an exposure apparatus and exposure-transferred to a resist film on a semiconductor device, a defected area will be generated on a circuit pattern to be finally formed on the semiconductor device.

This invention is not limited to the structures explained above in the embodiments, but various changes and modifications can be made without departing from other structures of the invention. For example, while the case of manufacturing a dug-down Levenson Type phase shift mask using a mask blank was explained in the embodiments of this invention, the invention is not limited thereto but can be used for manufacturing a binary mask.

### REFERENCE NUMERALS

1 transparent substrate
2 dug-down portion
3 light shielding film
3a light shielding pattern
4 hard mask film
4a hard mask pattern
5a resist pattern
6 resist pattern
11A transfer pattern forming region
11B outer peripheral region
11S main surface
15 alignment pattern
16 transfer pattern
100 mask blank
200 phase shift mask

1. A mask blank having a structure where a light shielding film and a hard mask film are stacked in this order on a transparent substrate,
wherein the hard mask film is made of a material containing one or more elements selected from silicon and tantalum,
wherein the light shielding film has an optical density to ArF excimer laser exposure light of more than 2.0,
wherein the light shielding film is a single layer film having a composition gradient portion with increased oxygen content on a surface at a side of the hard mask film and a region close thereto,
wherein the light shielding film is made of a material containing chromium, oxygen, and carbon,
wherein a part of the light shielding film excluding the composition gradient portion has chromium content of 50 atom % or more,
wherein the light shielding film has a maximum peak of N1s narrow spectrum, obtained by analysis of X-ray photoelectron spectroscopy, of lower detection limit or less, and
wherein the part of the light shielding film excluding the composition gradient portion has a maximum peak of Cr2p narrow spectrum, obtained by analysis of X-ray photoelectron spectroscopy, at binding energy of 574 eV or less.

2. The mask blank according to claim 1, wherein ratio of carbon content [atom %] divided by total content [atom %] of chromium, carbon, and oxygen of the part of the light shielding film excluding the composition gradient portion is 0.1 or more.

3. The mask blank according to claim 1, wherein the composition gradient portion of the light shielding film has a maximum peak of Cr2p narrow spectrum obtained by analysis of X-ray photoelectron spectroscopy at binding energy of 576 eV or more.

4. The mask blank according to claim 1, wherein the light shielding film has a maximum peak of Si2p narrow spectrum obtained by analysis of X-ray photoelectron spectroscopy of lower detection limit or less.

5. The mask blank according to claim 1, wherein the part of the light shielding film excluding the composition gradient portion has chromium content of 80 atom % or less.

6. The mask blank according to claim 1, wherein the part of the light shielding film excluding the composition gradient portion has carbon content of 10 atom % or more and 20 atom % or less.

7. The mask blank according to claim 1, wherein the part of the light shielding film excluding the composition gradient portion has oxygen content of 10 atom % or more and 35 atom % or less.

8. The mask blank according to claim 1, wherein the part of the light shielding film excluding the composition gradient portion has difference in content of each constituent element in thickness direction that is less than 10 atom %.

9. The mask blank according to claim 1, wherein the light shielding film has a thickness of 80 nm or less.

10. A method of manufacturing a phase shift mask using the mask blank according to claim 1, comprising the steps of:
forming a light shielding pattern on the hard mask film through dry etching using fluorine-based gas with a resist film having a light shielding pattern formed on the hard mask film as a mask;
forming a light shielding pattern on the light shielding film through dry etching using a mixed gas of chlorine-based gas and oxygen gas with the hard mask film having the light shielding pattern formed thereon as a mask; and
forming a dug-down pattern on the transparent substrate through dry etching using fluorine-based gas with a resist film having a dug-down pattern formed on the light shielding film as a mask.

11. A method of manufacturing a semiconductor device comprising the step of exposure-transferring a transfer pattern on a resist film on a semiconductor substrate using a phase shift mask obtained by the method of manufacturing a phase shift mask of claim 10.
